(19) United States
(12) Patent Application Publication
(10) Pub. No.: US 2013/0199603 A1
(43) Pub. Date: Aug. 8, 2013

(54) PHOTOSENSITIVE SOLID STATE HETEROJUNCTION DEVICE

(71) Applicants: Henry Snaith, Oxford (GB); Pablo Docampo, Oxford (GB)

(72) Inventors: Henry Snaith, Oxford (GB); Pablo Docampo, Oxford (GB)

(73) Assignee: ISIS INNOVATION LIMITED, Oxford (GB)

(21) Appl. No.: 13/634,157

(22) PCT Filed: Mar. 11, 2011
(86) PCT No.: PCT/GB2011/050491

§ 371 Date: Apr. 24, 2013

(30) Foreign Application Priority Data
Mar. 11, 2010 (GB) 1004106.9

(51) Int. Cl. H01L 51/42

(52) U.S. Cl. CPC H01L 51/4213
USPC 136/255; 257/40; 438/99

(57) ABSTRACT

The invention provides a solid-state p-n heterojunction comprising an organic p-type material in contact with an n-type material wherein said heterojunction is sensitised by at least one sensitizing agent, characterised in that the device comprises a cathode separated from said n-type material by a porous barrier layer of at least one insulating material. Also provided are opto-electronic devices such as solar cells or photo-sensors comprising such a p-n heterojunction, and methods for the manufacture of such a heterojunction or device.

The present invention relates to a solid-state p-n heterojunction and to its use in optoelectronic devices, in particular in solid-state dye-sensitized solar cells (SDSCs) and corresponding light sensing devices. Most particularly, the present invention relates to optoelectronic devices having high stability in use.

The junction of an n-type semiconductor material (known as an electron transporter) with a p-type semiconductor material (known as a hole-transporter) is perhaps the most fundamental structure in modern electronics. This so-called “p-n heterojunction” forms the basis of most modern diodes, transistors and related devices including opto-electronic devices such as light emitting diodes (LEDs), photovoltaic cells, and electronic photo-sensors.

A realization of the pressing need to secure sustainable future energy supplies has led to a recent explosion of interest in photovoltaics (PV). Conventional semi-conductor based solar cells are reasonably efficient at converting solar to electrical energy. However, it is generally accepted that further major cost reductions are necessary to enable widespread uptake of solar electricity generation, especially on a larger scale. Dye-sensitized solar cells (DSCs) offer a promising solution to the need for low-cost, large-area photovoltaics. Typically, DSCs are composed of mesoporous TiO₂ (electron transporter) sensitized with a light-absorbing molecular dye, which in turn is contacted by a redox-active hole-transporting medium (electrolyte). Photo-excitation of the sensitizer leads to the transfer (injection) of electrons from the excited dye into the conduction band of the TiO₂. These photo-generated electrons are subsequently transported to and collected at the anode. The oxidized dye is regenerated via hole-transfer to the redox active medium with the holes being transported through this medium to the cathode.

The most efficient DSCs are composed of TiO₂ in combination with a redox active liquid electrolyte, or a “gel” type semi-solid electrolyte. Those incorporating an iodide/triiodide redox couple in a volatile solvent can convert over 12% of the solar energy into electrical energy. However, this efficiency is far from optimum. Even the most effective sensitizer/electrolyte combination which uses a ruthenium complex with an iodide/triiodide redox couple sacrifices approx. 600 mV in order to drive the dye regeneration/iodide oxidation reaction. Furthermore, such systems are optimised to operate with sensitizers which predominantly absorb in the visible region of the spectrum thereby losing out on significant photocurrent and energy conversion. Even in the most efficiently optimised liquid electrolyte-based DSCs, photons which are not absorbed between 600 and 800 nm amount to an equivalent of 7 mA/cm⁻² loss in photocurrent under full sun conditions. Other problems with the use of liquid electrolytes are that these are corrosive and often prone to leakage, factors which become particularly problematical for larger-scale installations or over longer time periods.

More recent work has focused on creating gel or solid-state electrolytes, or entirely replacing the electrolyte with a solid-state molecular hole-transporter, which transports the charge by movement of electrons rather than electrolytes, which rely on movement of ions. Molecular hole-transporters are much more appealing for large scale processing and durability due to their lack of corrosive properties and saving in potential by avoiding the need to drive the redox couple. Of these alternatives, the use of a molecular hole-transporter appears to be the most promising. Though these solid-state DSCs (SDSCs) are a proven concept, the most efficient still only convert just over 5% of the solar energy into usable electrical power. This is still a long way off the efficiency of the liquid based cells and will require further optimisation before SDSCs can become a viable commercial prospect in routine applications.

The rates of many of the charge-transfer steps in a DSC-type optoelectronic device are highly dependent upon the environment in which the relevant materials are held. For example, although the “injection” step of transferring an excited electron from a sensitizer to the n-type material is essentially quantitative in electrolyte-based DSCs, in solid state devices this step is relatively slow and a significant proportion of electrons are quenched by other pathways before they can be transferred to the n-type material. Similarly, the characteristics of such devices are also controlled by the components which are required to form them and so, for example, in cells containing the aggressively corrosive iodide/triiodide redox couple, certain components must be physically isolated from this electrolyte if the cell is to have a significant working lifetime. In a solid-state device, however, this aggressive environment is removed and so correspondingly is the need for physical isolation of the redox active medium from other cell components. As a result of these and other factors, many of the approaches used to improve the efficiency of electrolyte-type DSCs are not applicable in the solid state devices.

For a DSC to be economically viable, it must have an operational lifetime of at least 10 years, and more typically at least 20 years under full sun conditions. Evidently, organic components subject to full solar irradiation for many years are susceptible to degradation. In the case of DSCs, and particularly solid-state DSCs (SDSCs—having a molecular hole transporter rather than an ionic electrolyte), the organic materials are highly stable under solar irradiation providing oxygen is excluded from the device. In the presence of oxygen, however, sunlight causes oxidative degradation which would relatively quickly break down the organic components and thus preclude an effective commercial lifetime for the device.

The combination of oxygen and sunlight is catastrophic for stability of organic semiconductors. However, with relatively cheap encapsulation techniques, the oxygen can be excluded enabling suitable stability of many organic materials. The solid-state dye-sensitized solar cell should be an ideal concept for excellent stability: It is composed of a preformed mesoporous metal oxide electrode which is not susceptible to structural degradation, unlike polymer solar cells. The metal oxide structure is sensitized with a light absorbing dye and infiltrated with a molecular hole-transporter. The dye is most stable when it is in the neutral state. Following light absorption, the dye is completely regenerated by the hole transporter within a few hundred picoseconds, implying that dye degradation should occur orders of magnitude slower than in the iodide/triiodide based liquid electrolyte cell, where dye regeneration occurs in the microsecond timescale. Despite these apparent advantages over competing concepts, until now the stability of solid-state DSCs has not been tested to any significant degree.

Although SDSCs have not been produced on a commercial scale at present, the inventors have applied methods equivalent to known and commercially viable encapsulating techniques to these devices, so as to allow exclusion of oxygen and thus provide and test oxidative stability. However, they have now discovered that devices which are functional for hours or days in an aerobic environment lose their efficiency within minutes if exposed to sunlight in the absence of oxygen. This in itself is an unexpected finding because it would be expected that oxygen and sunlight would combine to gradually degrade performance. Repeated tests have, however, shown that an encapsulated SDSC cannot retain solar conversion efficiency beyond a few minutes (less than 20 minutes) in full sun in the absence of oxygen. Upon encapsulation in an inert atmosphere and operation under sun light, the devices rapidly loose their open-circuit voltage and fill factor due to a dramatic reduction in the cell shunt resistance, rendering them useless. More surprisingly still, the devices completely recover to initial performance when re-exposed to air.

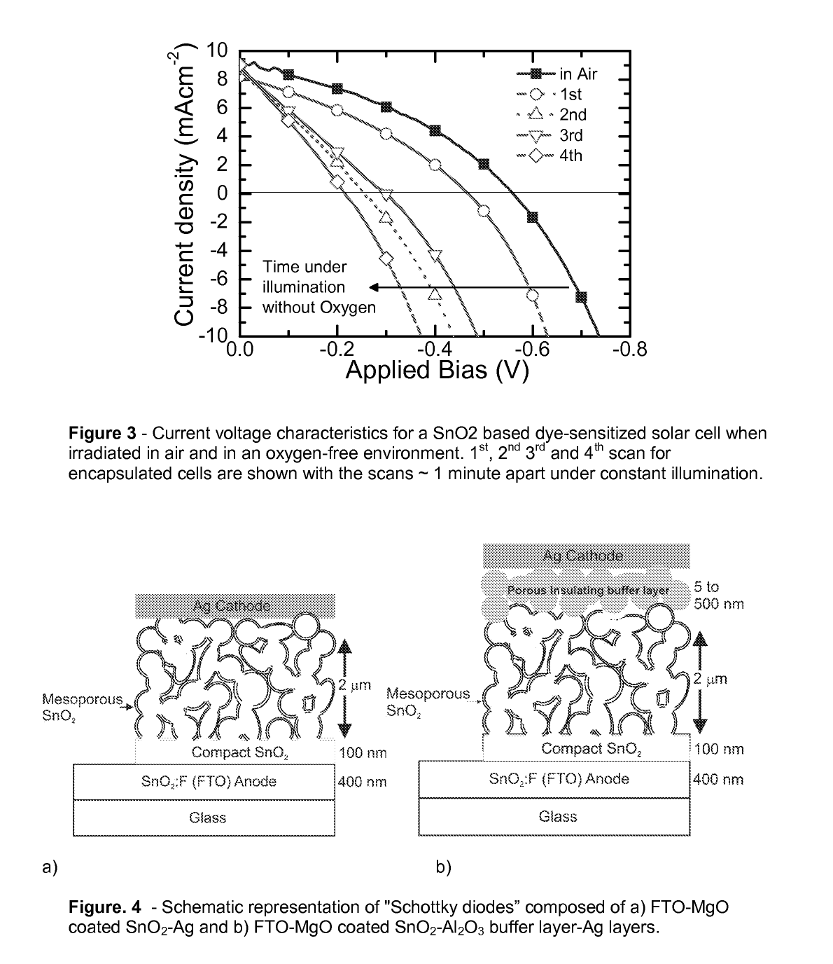

Details of the inventor's studies are described below. The results, shown for example in FIG. 3, indicate that within less than ten minutes of exposure to full sun conditions in the absence of air, the voltage generated by a SDSC drops dramatically. Evidently, a commercially viable DSC can neither lose performance over minutes, nor be permitted contact with atmospheric oxygen or the organic components will degrade.

After further experimentation, the present inventors have now established that by physical separation of the mesoporous anode from the cathode, particularly by means of a porous insulating structure which allows penetration of the hole transporting material, solid-state dye sensitised solar cells may be created that retain their full performance when encapsulated in the absence of oxygen, thus allowing for SDSCs with long term stability to an outdoor environment.

In a first aspect, the present invention therefore provides a solid-state p-n heterojunction (e.g. SDSC) comprising an organic p-type material in contact with an n-type material wherein said heterojunction is optionally sensitised by one or more sensitizing agent, characterised in that the device comprises a cathode separated from said n-type material by a porous barrier layer of at least one insulating material. Preferably, said n-type material and said cathode are separated by a distance of no less than 1 nm at their closest point, by said barrier layer. The said barrier layer will cover substantially the whole of the area between the cathode and the anode. For example, the barrier layer may cover at least 95%, preferably at least 99% and most preferably at least 99.9% of the area of overlap between the n-type material and the cathode.

The junction will preferably comprise a solid p-type material (hole transporter) in the form of an organic semiconductor, such as a molecular, oligomeric or polymeric hole transporter. In one embodiment the p-type material is an optionally amorphous molecular organic compound. The hole transporter is such that the conduction occurs by means of electron (hole) transport and not by the movement of charged ions through the material.

The presence of a porous barrier layer of insulating material is a key aspect of the present invention. Such a layer should preferably be sufficiently porous so as to permit a conduction path from the electron-deficient dye to the cathode by means of the organic hole transporter but sufficiently insulating to prevent direct charge transfer between the cathode and the n-type semiconductor. In this respect, it will be preferable that the porous barrier layer is formed from at least one insulating material with a resistivity of greater than 10⁹ Ωcm. Suitable barrier layers are described in detail herein.

One of the key features of the heterojunctions of the present invention is that they are less susceptible to a light-induced decrease in shunt-resistance than previously known SDSCs. In all appropriate aspects of the invention, therefore, the solid-state DSCs may be resistant to light-induced decrease in shunt resistance. For example, they may maintain not less than 75% of their initial energy conversion efficiency when exposed to full sun illumination under anaerobic conditions for at least 20 minutes. Such features are described in greater detail herein below.

The solid-state p-n heterojunctions of the present invention are particularly suitable for use in solar cells, photo-detectors and other optoelectronic devices. In a second aspect, the present invention therefore provides an optoelectronic device comprising at least one solid state p-n heterojunction of the invention, as described herein. Such devices will optionally be encapsulated. Such encapsulation will preferably substantially isolate the device(s) from atmospheric oxygen.

All references to a heterojunction herein may be taken to refer equally to an optoelectronic device, including referring to a solar cell or to a photo-detector where context allows. Similarly, while solid-state DSCs are frequently used herein as illustration, it will be appreciated that such heterojunctions may equally be applied to other corresponding optoelectronic devices including all those described in all sections herein.

In a corresponding further aspect, the present invention additionally provides the use of a porous barrier layer to reduce the light-induced drop in shunt resistance in a solid-state p-n heterojunction under anaerobic conditions. This will preferably be a heterojunction of the present invention as described herein (e.g. a SDSC). All preferred features of the heterojunctions described herein apply correspondingly to the use aspect of the invention.

The use in all appropriate aspects of the invention will preferably be in an optoelectronic device such as any of those described herein, e.g. in a solar cell or photodetector, particularly a SDSC.

The use of the present invention will preferably be to maintain the efficiency of a device (e.g. SDSC) at no less than 75% of its initial efficiency for a period of no less than 20 minutes under full sun illumination in the substantial absence of oxygen.

In a still further aspect, the present invention provides a method for the manufacture of a solid-state p-n heterojunction comprising a cathode separated from said n-type material by a porous barrier layer of at least one insulating material, said method comprising:
a) coating a cathode, preferably a transparent cathode (e.g. a Fluorinated Tin Oxide—FTO cathode) with a compact layer of an n-type semiconductor material (such as any of those described herein);
b) forming a porous (preferably mesoporous) layer of an n-type semiconductor material (such as any of those described herein) on said compact layer,
c) surface sensitizing said compact layer and/or said porous layer of n-type material with at least one sensitizing agent;
d) forming a porous barrier layer of an insulating material on said porous layer of n-type material;
e) forming a layer of a solid state p-type semiconductor material (preferably an organic hole transporting material such as any of those described herein) in contact with said porous layer of an n-type semiconductor material and penetrating said porous barrier layer; and
f) forming an anode, preferably a metal anode (e.g. a silver or gold anode) on said porous barrier layer, in contact with said p-type semiconductor material.

The surface sensitizing of the layer (e.g. porous layer) of n-type semiconductor material is preferably by surface absorption of the sensitizing agent. This sensitizing agent may be absorbed by contact of the surface with a solution of the desired sensitizing agent. The addition of the sensitizing agent or agents may occur before the formation of the barrier layer and/or after the formation of that layer.

Optionally, no sensitizing agent may be employed, in combination with an organic hole-conductor which also absorbs visible light. This type of non-sensitized solid-state device will be referred to as a “hybrid” polymer solar cell, where the term hybrid referred to the combination of a mesoporous metal oxide and a semiconducting organic hole-transporter. Similar to that described in reference: Coakley et al. (attached)

The solid-state p-n heterojunction formed or formable by any of the methods described herein evidently constitutes a further aspect of the invention, as do optoelectronic devices such as photovoltaic cells or light sensing devices comprising at least one such heterojunction.

The functioning of a DSC relies initially on the collection of solar light energy in the form of capture of solar photons by a sensitizer (typically a molecular, metal complex, or polymer dye). The effect of the light absorption is to raise an electron into a higher energy level in the sensitizer. This excited electron will eventually decay back to its ground state, but in a DSC, the n-type material in close proximity to the sensitizer provides an alternative (faster) route for the electron to leave its excited state, viz. by “injection” into the n-type semiconductor material. This injection results in a charge separation, whereby the n-type semiconductor has gained a net negative charge and the dye a net positive. Since the dye is now charged, it cannot function to absorb a further photon until it is “regenerated” and this occurs by passing the positive charge (“hole”) on to the p-type semiconductor material of the junction (the “hole transporter”). In a solid state device, this hole transporter is in direct contact with the dye material, while in the more common electrolytic dye sensitised photocells, a redox couple (typically iodide/triiodide) serves to regenerate the dye and transports the “hole species” (triiodide) to the counter electrode. Once the electron is passed into the n-type material, it must then be transported away, with its charge contributing to the current generated by the solar cell.

While the above is a simplified summary of the ideal working of a DSC, there are certain processes which occur in any practical device in competition with these desired steps and which serve to decrease the conversion of sunlight into useful electrical energy. Decay of the sensitizer back to its ground state was indicated above, but in addition to this, there is the natural tendency of two separated charges of opposite sign to re-combine. This can occur by return of the electron into a lower energy level of the sensitizer, or by recombination of the electron directly from the n-type material to quench the hole in the p-type material. In an electrolytic DSC, there is additionally the opportunity for the separated electron to leave the surface of the n-type material and directly reduce the iodide/iodine redox couple. Evidently, each of these competing pathways results in the loss of potentially useful current and thus a reduction in cell energy-conversion efficiency.

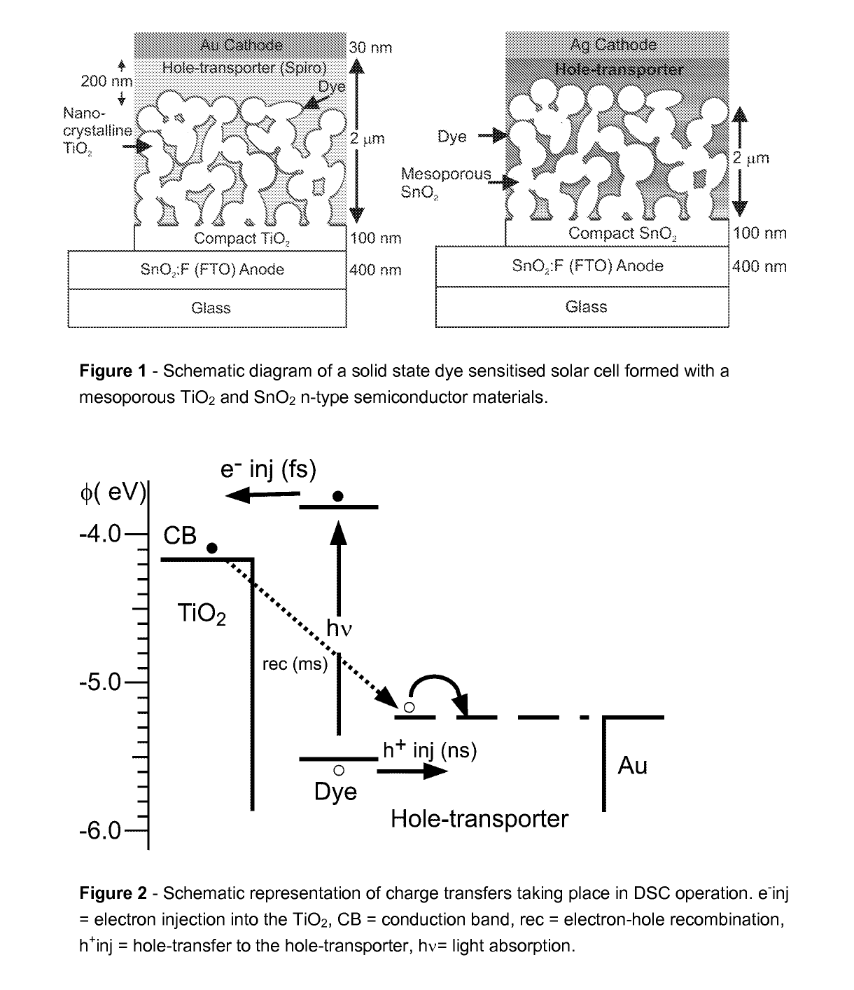

A schematic diagram indicating a typical structure of the solid-state DSC is given in attached FIG. 1 and a diagram indicating some of the key steps in electrical power generation from a DSC is given in attached FIG. 2.

The varying kinetics of the steps in the energy conversion process have greater and lesser effects upon the overall efficiency and stability of a DSC. For example, the dye is most stable in its neutral state and so the very rapid dye regeneration (such as that provided by a solid-state hole-transporter rather than an ionic electrolyte) not only helps to avoid recombination of the negative charge with the dye, but also renders it more stable to long term use. Similarly, varying the energy level changes and thus kinetics of the various electron transfers involved can improve injection efficiency but care must be taken that recombination with the dye is not also enhanced. Many of these processes have been studied in detail in various types of cell, but it has not previously been suggested that the use of a porous barrier layer to separate the cathode from the n-type material might provide an improvement in sustained efficiency under anaerobic conditions.

One of the key aspects of the present invention is the use of a barrier layer between the cathode and the n-type semiconductor material of the solid state heterojunction. Such barrier layers have not previously been employed in solid state p-n heterojunctions having an organic hole transporter because there is no known suggestion of any advantage in including such a barrier. Barrier layers have been employed in the case of liquid or gel electrolyte heterojunctions (DSCs) because such electrolytes do not have the structural properties to allow generation of a complete cell without additional support. The barrier layer is provided in these cases for structural rather than electronic properties. No advantage has previously been envisaged for including a barrier layer in non-electrolyte heterojunctions where structural support is not required. Such barriers have thus been avoided because there is a concomitant increase the distance over which the hole transporter must conduct the charge, and the greater this conduction path-length the greater the internal resistance of the device. In one embodiment, therefore, all aspects of the present invention may preferably relate to solid-state p-n heterojunctions not containing an ionic hole-transporting species (electrolyte). As an example, the heterojunction and/or corresponding devices, such as DSCs should not contain any iodine/iodide redox couples, such as I₂/I³⁻.

The use of the term “electrolyte” is not entirely consistent in the prior art, with some authors using the term “electrolyte” to include non-ionic charge transporting species such as molecular hole transporters. The general convention, however, which is adopted herein, is that the term “electrolyte” refers to a medium through which charge is transported by the movement of ions. Thus, a polymer or gel electrolyte is distinct from the organic hole transporters employed in all aspects of the present invention because the former relies on the movement of ions to carry charge, while the latter conducts by passage of electrons. Thus, the SDSCs and related aspects of the present invention relate to non-electrolyte devices in that they preferably do not contain any “electrolyte”, being any species which conducts by ion movement, but rather contain a solid-state “hole transporter” which conducts electrons.

Hole transport by the use of electron conductors rather than ionic movement is believed to offer significant potential benefit in the long term stability of DSCs because the dye molecules are regenerated orders of magnitude faster using molecular hole transporters and thus spend a much shorter proportion of their time in their less stable charged form.

The present inventors have tested to see whether the observed drop in shunt resistance under illumination in the absence of oxygen is attributable to any of the previously suggested potential limitations of SDSCs, such as an significant increase in the conductivity in the TiO₂, resulting in either increased recombination at the heterojunction, or short-circuiting of the function of the compact metal-oxide under-layer (which serves to block short-circuit by hole-collection at the anode). An increase in n-type material conductivity could be caused by either nitrogen doping of the TiO₂ under light, or due to increased oxygen vacancy density in the TiO₂, with each oxygen vacancy liberating a free electron to the lattice. Testing of comparative cells and equivalent diodes has, however, shown that none of these previously-considered potential points of short-circuit or recombination can account for the observed light-induced decrease in oxygen-free performance.

The tests which have been performed are described here: In a first test, different “inert” gasses were used within which the TiO₂ based devices were encapsulated, specifically Argon and Nitrogen. Similar rapid degradations in photovoltaic performance were observed with the two gasses, suggesting that Nitrogen doping of the TiO₂ is not the cause for the drop in shunt resistance within the devices. In a second test, the compact underlayer was changed from TiO₂ to SnO₂. SnO₂ is more stoiciometric than TiO₂ and we would expect to have greater stability in this layer under UV illumination, especially considering the wider band gap of SnO₂ rendering it less absorbing to UV radiation. The devices incorporating the SnO₂ underlayers worked similarly well in air, however, once again, the devices degraded rapidly once illuminated while having been sealed in Nitrogen. As a third test, the entire mesoporous metal oxide and underlayer was changed from anataze phase TiO₂ to rutile phase SnO₂. Once again, when encapsulated in nitrogen, the devices degraded rapidly. Since we would expect SnO₂ to be more stable to UV radiation, this latter test suggests that the problem does not lie intrinsically in the mesoporous metal oxide. No previously postulated weakness could therefore account for the observed surprising drop in shunt resistance.

A key aspect of the present invention, which has surprisingly been established to allow encapsulation of the heterojunctions to exclude oxygen without causing a photo-induced drop in shunt-resistance is the use of a porous “barrier” or “blocking” layer. Such a barrier layer should be sufficiently insulating to prevent any electrical contact between the n-type semiconductor material and the cathode, but sufficiently porous to allow penetration by the hole transporting material and to allow a sufficient path for the charge from the dye to be conducted to the cathode. Similarly, the barrier layer should be sufficiently thick to reliably insulate the n-type material from the cathode but should not be thicker than necessary due to the increase in resistance caused by a longer path of conduction through the hole transporter.

Insulating metal oxides, either alone or in combination with other metal salts are examples of suitable materials which can be formed into a porous barrier layer. Examples of suitable metal oxides include, but not limited to: Al₂O₃, SiO₂, ZrO, MgO, HfO₂, Ta₂O₅, Nb₂O₅, Nd₂O₃, Sm₂O₃, La₂O₃, Sc₂O₃, Y₂O₃, NiO, MoO₃, MnO and compound metal oxides such as SiAlO_{3,5}, Si₂AlO_{5,5}, SiTiO₄ and/or AlTiO₅. Mixtures of any of these oxides and/or compound oxides are evidently also suitable.

Insulating polymers, either alone or in combination with each other or with other materials are also highly suitable materials for forming a porous barrier layer. Examples of suitable polymers include: poly-styrene, acrelate, methacrylate, methylmethacrylate, ethelene oxide, ethelene glycol, cellulose and/or imide polymers or mixtures thereof.

Block copolymers are a subset of insulating polymers which are highly suitable either alone or in combination with each other, with other polymers and/or with other materials. Examples of suitable block copolymers include: polyisoprene-block-polystyrene, poly(ethylene glycol)-block-poly(propylene glycol)-block-poly(ethylene glycol), polystyrene-block-polylactide, and/orpolystyrene-block-poly(ethylene oxide) or mixtures thereof.

The thickness of the insulating barrier layer should be sufficient to provide an insulating effect without being so thick that a significant increase in the internal resistance is caused. Suitable thicknesses will be readily established by those of ordinary skill depending upon the barrier material, the porosity and the nature of the hole transporter. Typically, suitable thicknesses range from 0.5 to 1000 nm (e.g. 1 to 1000 nm or 2 to 500 nm), preferably 1 to 100 nm (e.g. 2 to 100 nm), more preferably 5 to 50 nm. For the barrier films fabricated from mesoporous pasted layers (e.g. of metal oxide) and/or from block copolymers, a most preferable thickness is around 50 nm (e.g. 30 to 70 nm). For barrier layers fabricated by sputter deposition, evaporation or spray pyrolysis deposition (e.g. of metal oxides), the most preferable range is 1 to 25 nm, especially 5 to 15 nm.

The porosity of the insulating barrier layer should be such as to allow this to be impregnated with the hole transporter with a sufficient degree of penetration that a reliable conduction path from the charged dye to the cathode is provided. Examples of suitable porosities range from 10 to 90%, preferably 25 to 75%, more preferably 40 to 60%.

The material for forming the insulating barrier layer should evidently have a low conductivity and thus high resistivity. A suitable conductivity will be established by routine testing by one of skill in the art, such that the resulting device is effective and capable of encapsulation without any significant light-induced drop in shunt resistance. Typically, however, a suitable insulator will have a conductivity of less than 10⁻⁹ Scm⁻¹. Correspondingly, a suitable insulator will typically have a resistivity of greater than 10⁹ Ωcm. Conductivity and/or resistivity may be measured by standard techniques, such as by a 4 point probe conductivity measurement, as described in S. M. Sze in “Semiconductor Devices Physics and Technology”, 2nd Edition, Wiley Page 54.

The p-n heterojunctions of the invention, as well as those used with or generated by alternative aspects of the invention are light sensitive and as such include at least one light sensitizing agent (sensitizer). Referred to herein as the sensitizer or sensitizing agent, this material may be one or more dyes or any material which generates an electronic excitation as a result of photon absorption and which is capable of electron injection into the n-type material. The most commonly used light sensitising materials in electrolytic DSCs are organic or metal-complexed dyes. These have been widely reported in the art and the skilled worker will be aware of many existing sensitizers, all of which are suitable in all appropriate aspects of the invention and consequently are reviewed here only briefly.

A common category of organic dye sensitizers are indolene based dyes, of which D102, D131 and D149 (shown below) are particular examples.

The general structure of indolene dyes is that of Formula sI below:

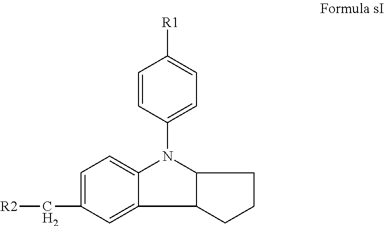

wherein R1 and R2 are independently optionally substituted alkyl, alkenyl, alkoxy, heterocyclic and/or aromatic groups, preferably with molecular weight less than around 360 amu. Most preferably, R1 will comprise aralkyl, alkoxy, alkoxy aryl and/ or aralkenyl groups (especially groups of formula CₓH_{y}O_{z} where x, y and z are each 0 or a positive integer, x+z is between 1 and 16 and y is between 1 and 2x+1) including any of those indicated below for R1, and R2 will comprise optionally substituted carbocyclic, heterocyclic (especially S and/or N-containing heterocyclic)cycloalkyl, cycloalkenyl and/or aromatic groups, particularly those including a carboxylic acid group. All of the groups indicated below for R2 are highly suitable examples. One preferred embodiment of R2 adheres to the formula CₓH_{y}O_{z}NᵥS_{w} where x, y, z, v and w are each 0 or a positive integer, x+z+w+v is between 1 and 22 and y is between 1 and 2x+v+1. Most preferably, z≧2 and in particular, it is preferable that R2 comprises a carboxylic acid group. These R1 and R2 groups and especially those indicated below may be used in any combination, but highly preferred combinations include those indicated below:

| Dye Name | R1 | R₂ |
|---|---|---|
| D₁₄₉ | Ph₂C═CH | 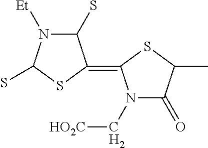 |
| D₁₀₂ | Ph₂C═CH | 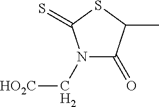 |
| D₇₇ | OMe | 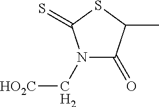 |
| D₁₀₃ | 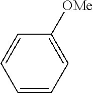 | 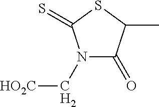 |
| D₁₃₁ | Ph₂C═CH | 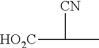 |
| D₁₂₀ | OMe | 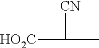 |

Indolene dyes are discussed, for example, in Horiuchi et al. J Am. Chem. Soc. 126 12218-12219 (2004), which is hereby incorporated by reference.

A further common category of sensitizers are ruthenium metal complexes, particularly those having two bipyridyl coordinating moieties. These are typically of formula sII below

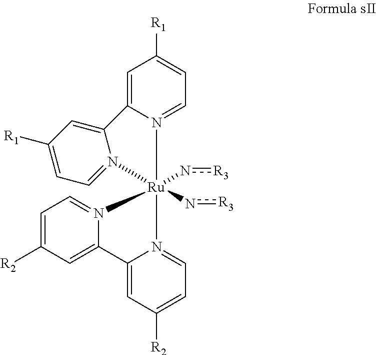

wherein each R1 group is independently a straight or branched chain alkyl or oligo alkoxy chain such as CₙH₂ₙ₊₁ where n is 1 to 20, preferably 5 to 15, most preferably 9, 10 or 11, or such as C—(—XCₙH₂ₙ—)m-XCₚH₂ₚ₊₁, where n is 1, 2, 3 or 4, preferably 2, m is 0 to 10, preferably 2, 3 or 4, p is an integer from 1 to 15, preferably 1 to 10, most preferably 1 or 7, and each X is independently O, S or NH, preferably O; and wherein each R2 group is independently a carboxylic acid or alkyl carboxylic acid, or the salt of any such acid (e.g. the sodium, potassium salt etc.) such as a CₙH₂ₙCOOY group, where n is 0, 1, 2 or 3, preferably 0 and Y is H or a suitable metal such as Na, K, or Li, preferably Na; and wherein each R3 group is single or double bonded to the attached N (preferably double bonded) and is of formula CHa-Z or C═Z, where a is 0, 1 or 2 as appropriate, Z is a hetero atom or group such as S, O, SH or OH, or is an alkyl group (e.g. methylene, ethylene etc.) bonded to any such a hetero atom or group as appropriate; R3 is preferably ═C═S.

A preferred ruthenium sensitizer is of the above formula sII, wherein each R1 is nonyl, each R2 is a carboxylic acid or sodium salt thereof and each R3 is double-bonded to the attached N and of formula ═C═S. R1 moieties of formula sII may also be of formula sIII below:

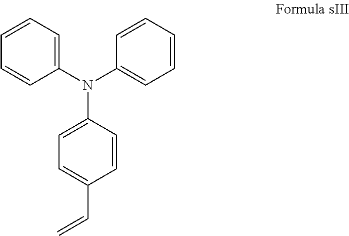 [SMILES: C=Cc1ccc(N(c2ccccc2)c2ccccc2)cc1]

Ruthenium dyes are discussed in many published documents including, for example, Kuang et al. Nano Letters 6 769-773 (2006), Snaith et al. Angew. Chem. Int. Ed. 44 6413-6417 (2005), Wang et al. Nature Materials 2, 402-498 (2003), Kuang et al. Inorganica Chemica Acta 361 699-706 (2008), and Snaith et al. J Phys, Chem. Lett. 112 7562-7566 (2008), the disclosures of which are hereby incorporated herein by reference, as are the disclosures of all material cited herein.

Other sensitizers which will be known to those of skill in the art include Metal-Phalocianine complexes such as zinc phalocianine PCH001, the synthesis and structure of which is described by Reddy et al. (Angew. Chem. Int. Ed. 46 373-376 (2007)), the complete disclosure of which (particularly with reference to Scheme 1), is hereby incorporated by reference.

Some typical examples of metal phthalocianine dyes suitable for use in the present invention include those having a structure as shown in formula sIV below:

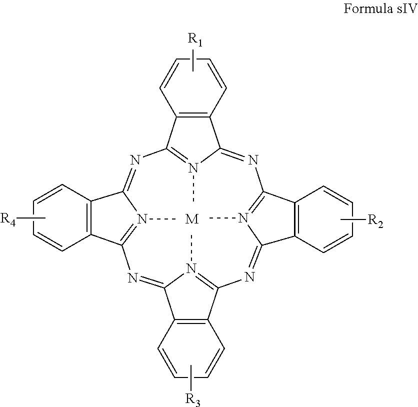

Wherein M is a metal ion, such as a transition metal ion, and may be an ion of Co, Fe, Ru, Zn or a mixture thereof. Zinc ions are preferred. Each of R1 to R4, which may be the same or different is preferably straight or branched chain alkyl, alkoxy, carboxylic acid or ester groups such as CₙH₂ₙ₊₁ where n is 1 to 15, preferably 2 to 10, most preferably 3, 4 or 5, with butyl, such as tertiary butyl, groups being particularly preferred, or such as OX or CO₂X wherein X is H or a straight or branched chain alkyl group of those just described. In one preferred option, each of R1 to R3 is an alkyl group as described and R4 is a carboxylic acid CO₂H or ester CO₂X, where X is for example methyl, ethyl, iso- or n-propyl or tert-, iso-, sec-or n-butyl. For example, dye TT1 takes the structure of formula sIV, wherein R1 to R3 are t-butyl and R4 is CO₂H.

Further examples of suitable categories of dyes include Metal-Porphyrin complexes, Squaraine dyes, Thiophene based dyes, fluorine based dyes, molecular dyes and polymer dyes. Examples of Squaraine dyes may be found, for example in Burke et al., Chem. Commun. 2007, 234, and examples of polyfluorene and polythiothene polymers in McNeill et al., Appl. Phys. Lett. 2007, 90, both of which are incorporated herein by reference. Metal porphyrin complexes include, for example, those of formula sV and related structures, where each of M and R1 to R4 can be any appropriate group, such as those specified above for the related phthalocyanine dyes:

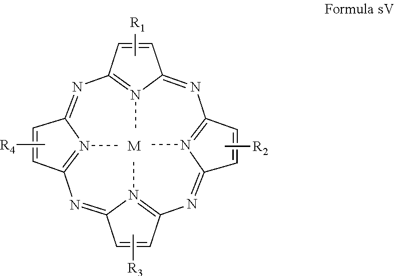

Squaraine dyes form a preferred category of dye for use in the present invention. The above Burke citation provides information on Squaraine dyes, but briefly, these may be, for example, of the following formula sVI

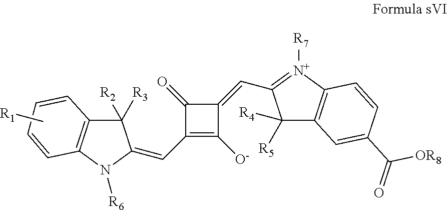

Wherein any of R1 to R8 may independently be a straight or branched chain alkyl group or any of R1 to R5 may independently be a straight or branched chain alkyloxy group such as CₙH₂ₙ₊₁ or CₙH₂ₙ₊₁O respectively where n is 1 to 20, preferably 1 to 12, more preferably 1 to 9. Preferably each R1 to R5 will be H, CₙH₂ₙ₊₁ or CₙH₂ₙ₊₁O wherein n is 1 to 8 preferably 1 to 3 more preferably 1 or two. Most preferably R1 is H and each R5 is methyl. Preferably each R6 to R8 group is H or CₙH₂ₙ₊₁ wherein n is 1 to 20, such as 1 to 12. For R6, n with preferably be 1 to 5 more preferably 1 to 3 and most preferably ethyl. For R7 n will preferably be 4 to 12, more preferably 6 to 10, most preferably 8, and for R8, preferred groups are H, methyl or ethyl, preferably H. One preferred squaraine dye referred to herein is SQ02, which is of formula sVI wherein R1 and R8 are H, each of R2 to R5 is methyl, R6 is ethyl, and R7 is octyl (e.g. n-octyl).

A further example category of valuable sensitizers are polythiophene (e.g. dithiophene)-based dyes, which may take the structure indicated below as formula sVII

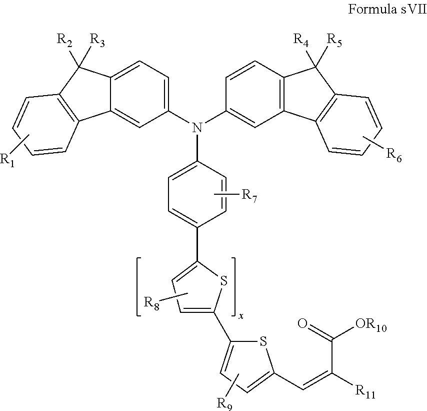

Wherein x is an integer between 0 and 10, preferably 1, 2, 3, 4 or 5, more preferably 1, and wherein any of R1 to R10 may independently be hydrogen, a straight or branched chain alkyl group or any of R1 to R9 may independently be a straight or branched chain alkyloxy group such as CₙH₂ₙ₊₁ or CₙH₂ₙ₊₁O respectively where n is 1 to 20, preferably 1 to 12, more preferably 1 to 5. It is preferred that each if R1 to R10 will independently be a hydrogen or CₙH₂ₙ₊₁ group where n is 1 to 5, preferably methyl, ethyl, n- or iso-propyl or n-, iso-, sec- or t-butyl. Most preferably, each of R2 to R4 will be methyl or ethyl and each of R1 and R6 to R10 will be hydrogen. The group R11 may be any small organic group (e.g. molecular weight less than 100) but will preferably be unsaturated and may be conjugated to the extended pi-system of the dithiophene groups. Preferred R11 groups include alkenyl or alkynyl groups (such as CₙH₂ₙ₋₁ and CₙH₂ₙ₋₃ groups respectively, e.g. where n is 2 to 10, preferably 2 to 7), cyclic, including aromatic groups, such as substituted or unsubstituted phenyl, piridyl, pyrimidyly, pyrrolyl or imidazyl groups, and unsaturated hetero-groups such as oxo, nitrile and cyano groups. A most preferred R11 group is cyano. One preferred dithiophene based dye is 2-cyanoacrylic acid-4-(bis-dimethylfluorene aniline)dithiophene, known as JK2.

Whilst it is envisaged that in general only a single dye sensitizer will be employed in the p-n heterojunctions herein described, two or more dye sensitizers may nevertheless be used. For example, all aspects of the present invention are suitable for use with co-sensitisation using a plurality of (e.g. at least 2, such as 2, 3, 4 or 5) different dye sensitizing agents. If two or more dye sensitizers are used, these may be chosen such that their respective emission and absorption spectra overlap. In this case, resonance energy transfer (RET) results in a cascade of transfers by which an electron excitation steps down from one dye to another of lower energy, from which it is then injected into the n-type material. However, it is preferable that the emission and absorption spectra of the individual dyes do not overlap to any significant extent. This ensures that all dye sensitizers are effective in the injection of electrons into the n-type material. Where two or more dye sensitizers are used, these will preferably have complimentary absorption characteristics. Some complimentary parings include, for example, the near-infra red absorbing zinc phalocianine dyes referred to above in combination with indoline or ruthenuim-based sensitizers to absorb the bulk of the visible radiation. As an alternative, a polymeric or molecular visible light absorbing material may be used in conjunction with a near IR absorbing dye, such as a visible light absorbing polyfluorene polymer with a near IR absorbing zinc phlaocianine or squaraine dye.

Two or more dye sensitizers may, for example, be used where the plamonic nanoparticles have two or more surface plasmon modes. Such a situation may arise either where a plurality of different plasmonic nanoparticles are used having different surface plasmon modes or, alternatively, where any given plasmonic nanoparticle may have different surface plasmon modes (for example due to its shape and/or dimensions). In cases such as this, it may be advantageous that each of the different surface plasmon modes overlaps with the absorption spectrum of a different dye sensitizer(s) thereby maximising the number of electrons injected into the n-type material.

An additional sensitizing agent may be used in any aspect of the present invention. These may be additional dye sensitizers (e.g. with complimentary absorption spectra) and/or may comprise at least one nanoparticulate metal having at least one surface plasmon mode in the visible to infra-red regions of the electromagnetic spectrum. As used herein, the term “surface plasmon” is intended to have its conventional meaning, namely a coherent oscillation free electrons on the surface of a metal at the interface between the metal and a dielectric material, where the real part of the dielectric function changes sign across metal-dielectric interface. The “mode” of the surface Plasmon reefers to the energy at which the optical photon can couple to the surface Plasmon. Nanoparticles having one or more surface plasmon modes between 400 nm and 2000 nm, preferably between 500 nm and 1000 nm, more preferably between 550 nm and 900 nm, are preferred for use in the invention. Suitable plasmonic materials include Ag, Au, Cu, Pt and mixtures thereof, especially Ag and Au, particularly preferably Au. Such plasmonic sensitizers are desirable in that they have a very high degree of light absorption and can be used to allow thinner heterojunction devices and/or to increase the light absorbed. The energy from this absorbed light is then passed to the dye sensitizer, which in turn injects an electron in the n-type material.

As used herein, the terms “nanoparticle” and “nanoparticulate” are not intended to impose any limitation on the desired shape of the plasmonic particles. Specifically, these terms are intended to encompass any structure having nanometre dimensions. Such a structure need not be spherical and indeed it is envisaged that other nanostructures may be equally suitable, or even more advantageous for use in the invention. Appropriate dimensions for the plasmonic nanostructures may readily be selected by those skilled in the art. Whilst such structures will typically be substantially spherical in shape, other nanostructures may also be used which are curved or shaped on the sub-wavelength scale and which therefore enable surface plasmon resonance through relatively broad band light incident at any angle. Other suitable nanostructures include, for example, nanorods, nanoprisms, nanostars, nanobars and nanowires. Such materials are known in the art and may be synthesised using methods disclosed in the literature, for example in Pastoriza-Santos, I. and Liz-Marzan, L. M., Synthesis of silver nanoprisms in DMF, Nano Letters 2 (8), 903 (2002) and Kumar, P. S. et al., High-yield synthesis and optical response of gold nanostars, Nanotechnology 19 (1) (2008)). Spherical nanoparticles may be synthesised using methods described in Example 1 herein.

Depending on the choice of nanoparticle, these may have more than one surface plasmon mode. For example, non-spherical structures such as nanobars will often have more than one surface plasmon resonance; the vis-near IR extinction spectrum of nanobars is characterised by a transverse plasmon resonance in the visible and a longitudinal resonance in the near-IR region (Nano Lett. Vol. 7, No. 4, 2007).

The energy resulting from excitation of surface plasmon modes by absorption of incident light may be transferred to the dye-sensitizing agent (dye sensitizer) by near and/or far-field effects. Near-field enhancement of absorption by the dye sensitizer will typically be observed where the plamonic nanoparticles have at least one dimension in the range 2 to 80 nm, particularly 2 to 20 nm. Far-field enhancement of absorption by the dye sensitizer will typically be observed where the plasmonic nanoparticles have at least one dimension in the range 20 to 200 nm, particularly 80 to 200 nm. Where spherical nanoparticles are employed these will typically have a mean average diameter in the range of from 10 to 100 nm. Nanoparticles of all shapes will typically have at least one dimension falling within one of the indicated ranges (e.g. from 2 to 200 nm) and may fall in these ranges in two or three dimensions. At least two dimensions within the indicated ranges is preferred. For elongated nanowires or nanorods, the direction of the long axis may extend from 10 to 4000 nm, preferably 20 10 1000 nm.

In order to function effectively, it is preferable that that the metal nanoparticles be coated in such a way that these are electrically isolated from at least one of the other components of the heterojunction, i.e. isolated either from the n-type material, the p-type organic hole-transporter or both the n-type material and the hole-transporter. In all instances they must be electronically isolated from the dye-sensitizer. Any coating material should be substantially transparent to the optical field but capable of electrically insulating the metal structures to at least some extent from the photogenerated charge within the device. Suitable coating materials include not only insulating, but also semi-conductor, materials. Insulating materials which may be used include those having a band gap of greater than 3 eV, preferably greater than 5 eV, more preferably 5 to 30 eV. Examples of suitable insulating materials include SiO₂, Al₂O₃, MgO, HfO, ZrO, ZnO, HfO₂, TiO₂, Ta₂O₅, Nb₂O₅, W₂O₅, In₂O₃, Ga₂O₃, Nd₂O₃, Sm₂O₃, La₂O₃, Sc₂O₃, Y₂O₃, NiO. Amongst these, SiO₂ is particularly preferred. Semi-conducting materials which may be used include oxides of Ti, Sn, W, Nb, Cu, Zn, Mo and mixtures thereof, e.g. TiO₂ and SnO₂.

The thickness of the coating on the nanoparticles will depend on the nature of the coating material, for example, whether this is a semi-conductor or insulator. A typical coating thickness may lie in the range 0.1 to 100 nm, more preferably 0.5 to 10 nm, e.g. 2 to 5 nm. Techniques for use in coating the nanoparticles are well known in the art.

Particularly preferred for use in the invention are silica-coated gold nanoparticles, for example those in which the diameter of the gold particles is, for example 5 to 25 nm, preferably about 13 nm and the thickness of the silica coating is 1 to 7 nm, preferably about 3 nm. These nanoparticles are preferably incorporated into the device by coating the dye-sensitized mesoporous n-type material with the silica-coated gold nanoparticles prior to hole-transporter infiltration.

Although many of the dyes indicated above show broad spectrum absorption in the visible region, plasmonic nanoparticles allow injection of electrons which result from excitation of surface plasmon modes by lower energy solar photons including, those of near infra-red frequencies. These are therefore advantageously combined with suitable dye sensitizers.

In all aspects of the present invention a solid state hole transporter is a key constituent, since this forms the p-type material of the p-n heterojunction. The hole transporter will preferably be a molecular p-type material rather than an inorganic material such as a salt, and more preferably will be an organic molecular material. Suitable materials will typically comprise an extended pi-bonding system through which charge may readily pass. Suitable materials will also preferably be amorphous or substantially amorphous solids rather than being crystalline at the appropriate working temperatures (e.g. around 30-70° C.). The organic hole-transporter would preferably have a high energy HOMO to LUMO transition, rendering its predominant function dye-regeneration and hole-transport. However, it may optionally have a narrow HOMO to LUMO transition, with its additional function being to absorb solar light, and subsequently transfer an electron to the n-type material, or its excited state energy to a dye molecule tethered to the n-type material surface. The then excited dye molecule would subsequently transfer an electron to the n-type material and the hole to the hole-transporter, as part of the photovoltaic conversion process.

According to a preferred embodiment, the solid state hole transporter is a material comprising a structure according to any of formulae (tI), (tII), (tIII), (tIV) and/or (tV) below:

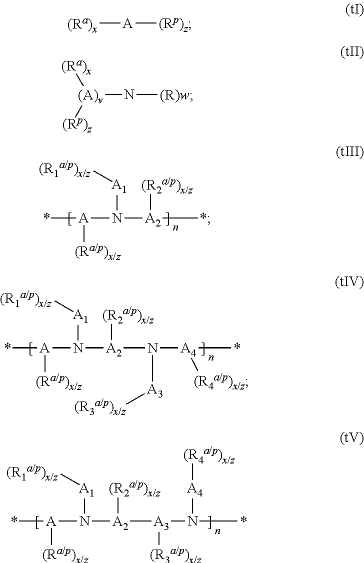

in which N, if present, is a nitrogen atom;
n, if applicable, is in the range of 1-20;
A is a mono-, or polycyclic system comprising at least one pair of a conjugated double bond (—C═C—C═C—), the cyclic system optionally comprising one or several heteroatoms, and optionally being substituted, whereby in a compound comprising several structures A, each A may be selected independently from another A present in the same structure (tII-tV);
each of A₁-A₄, if present, is an A independently selected from the A as defined above;
v in (tII) recites the number of cyclic systems A linked by a single bond to the nitrogen atom and is 1, 2 or 3;
(R)w is an optional residue selected from a hydrocarbon residue comprising from 1 to 30 carbon atoms, optionally substituted and optionally comprising 1 or several heteroatoms, with w being 0, 1 or 2 provided that v+w does not exceed 3, and, if w=2, the respective Rw₁ or Rw₂ being the same or different;
Ra represents a residue capable, optionally together with other Ra present on the same structure (tI-tV), of decreasing the melting point of an organic compound and is selected from a linear, branched or cyclic alkyl or a residue comprising one or several oxygen atoms, wherein the alkyl or the oxygen comprising residue is optionally halogenated;
x is the number of independently selected residues Ra linked to an A and is selected from 0 to a maximum possible number of substituents of a respective A, independently from the number x of other residues Ra linked to another A optionally present;
with the proviso that per structure (tI-tV) there is at least one Ra being an oxygen-containing residue as defined above; and, if several Ra are present on the same structure (I-V), they are the same or different; and wherein two or more Ra may form an oxygen-containing ring;
Rp represents an optional residue enabling a polymerisation reaction with compounds comprising structure (tI-tV) used as monomers, and/or a cross-linking between different compounds comprising structures (tI-tV);
z is the number of residues Rp linked to an A and is 0, 1, and/or 2, independently from the number z of other residues Rp linked to another A optionally present;
Rp may be linked to an N-atom, to an A and/or to a substituent Rp of other structures according (tI-tV), resulting in repeated, cross-linked and/or polymerised moieties of (tI-tV);
(R^{a/p})_{x/z} and (R₁₋₄^{a/P})_{x/z}, if present, represent independently selected residues Ra and Rp as defined above.

Preferably, the charge transporting material comprises compounds having the structures (tI)-(tV).

General reference to the several structures, such as in the references “(tI-tV)”, “(tVII-tXVI)”, or “A₁-A₄”, for example, means reference to any one selected amongst (tI), (tII), (tIII), (tIV), or (tV), any one selected amongst (tVII), (tVIII), (tIX), (tX), (tXI), (tXII), (tXIII), (tXIV), (tXV) or (tXVI), or any one selected amongst A₁, A₂, A₃ or A₄, respectively. In addition, in the charge transporting material for use in the invention, for example, different compounds of structures (tI-tV) may be combined and, if desired cross-linked and/or polymerised. Similarly, in any structure (tI-tV), different structures for A may be selected independently, for example from (tVII-tXVI).

According to a preferred embodiment, the organic charge transporting material of the device of the invention comprises a structure according to formula (tVI):

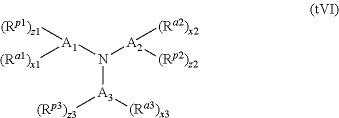

in which Ra1, Ra2 and Ra3 and x1, x2 and x3 are defined, independently, like Ra and x, respectively, above;

Rp1, Rp2 and Rp3 and z1, z2 and z3 are defined, independently, like Rp and z, respectively, above. Formula (tVI) thus represents a specimen of formula (tII) above, in which v is 3, and in which R(w) is absent.

Preferably, A is a mono- or polycyclic, optionally substituted aromatic system, optionally comprising one or several heteroatoms. Preferably, A is mono-, bi- or tricyclic, more preferably mono-, or bicyclic. Preferably, if one or more heteroatoms are present, they are independently selected from O, S, P, and/or N, more preferably from S, P and/or N, most preferably they are N-atoms.

According to a preferred embodiment, A is selected from benzol, naphthalene, indene, fluorene, phenanthrene, anthracene, triphenylene, pyrene, pentalene, perylene, indene, azulene, heptalene, biphenylene, indacene, phenalene, acenaphtene, fluoranthene, and heterocyclic compounds such as pyridine, pyrimidine, pyridazine, quinolizidine, quinoline, isoquinoline, quinoxaline, phtalazine, naphthyridine, quinazoline, cinnoline, pteridine, indolizine, indole, isoindole, carbazole, carboline, acridine, phenanthridine, 1,10-phenanthroline, thiophene, thianthrene, oxanthrene, and derivatives thereof, each of which may optionally be substituted.

According to a preferred embodiment, A is selected from structures of formula (tVII-tXIV) given below:

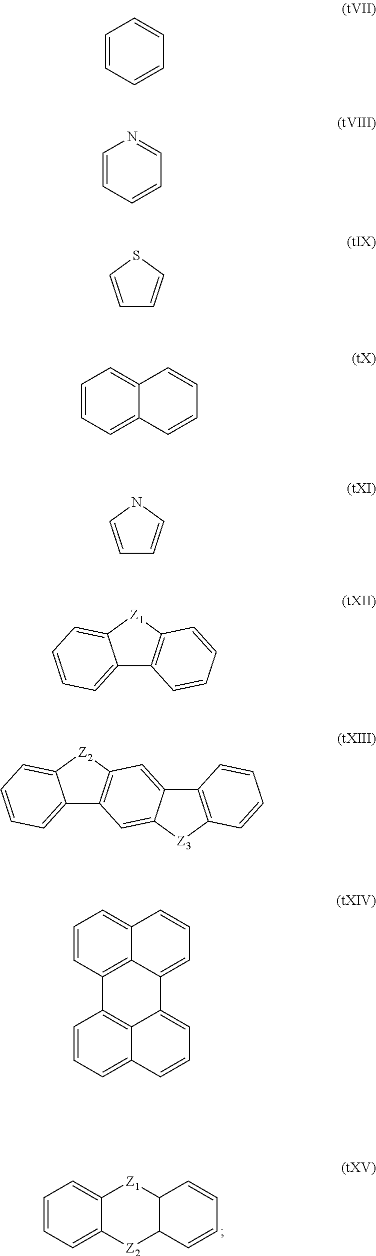

in which each of Z¹, Z² and Z³ is the same or different and is selected from the group consisting of O, S, SO, SO₂, NR¹, N⁺(R^{1′})(^{1″}), C(R²)(R³), Si(R^{2′})(R^{3′}) and P(O)(OR⁴), wherein R¹, R^{1′} and R^{1″} are the same or different and each is selected from the group consisting of hydrogen atoms, alkyl groups, haloalkyl groups, alkoxy groups, alkoxyalkyl groups, aryl groups, aryloxy groups, and aralkyl groups, which are substituted with at least one group of formula —N⁺(R⁵)₃ wherein each group R⁵ is the same or different and is selected from the group consisting of hydrogen atoms, alkyl groups and aryl groups, R², R³, R^{2′} and R^{3′} are the same or different and each is selected from the group consisting of hydrogen atoms, alkyl groups, haloalkyl groups, alkoxy groups, halogen atoms, nitro groups, cyano groups, alkoxyalkyl groups, aryl groups, aryloxy groups and aralkyl groups or R² and R³ together with the carbon atom to which they are attached represent a carbonyl group, and R⁴ is selected from the group consisting of hydrogen atoms, alkyl groups, haloalkyl groups, alkoxyalkyl groups, aryl groups, aryloxy groups and aralkyl groups.

Preferred embodiments of, structure (tXV) for A may be selected from structures (tXVI) and (tXVIa) below:

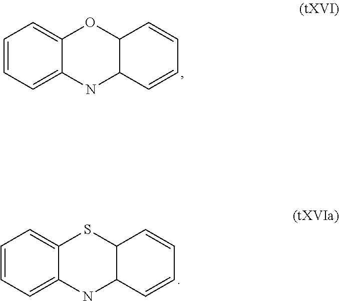 [SMILES: C1=CC2Nc3ccccc3OC2C=C1 ; C1=CC2Nc3ccccc3SC2C=C1]

Preferably, in any structure of (tI-tV) all A are the same, but differently substituted. For example, all A are the same, some of which may be substituted and some of which are not. Preferably, all A are the same and identically substituted.

Any A may be substituted by other substituents than Ra and/or Rp. Other substituents may be selected at the choice of the skilled person and no specific requirements are indicated herein with respect to them. Other substituents may thus correspond to (R)w in (tII) defined above. Other substituents and R(w) may generally be selected from linear, branched or cyclic hydrocarbon residues comprising from 1 to 30 carbon atoms, optionally substituted and optionally comprising 1 or several heteroatoms, for example. The hydrocarbon may comprise C—C single, double or triple bonds. For example, it may comprise conjugated double bonds. For example, optional other residues on A may be substituted with halogens, preferably —F and/or —Cl, with —CN or —NO₂, for example.

One or more carbon atoms of other substituents of A may or may not be replaced by any heteroatom and/or group selected from the group of —O—, —C(O)—, —C(O)O—, —S—, —S(O)—, SO₂—, —S(O)₂O—, —N═, —P═, —NR′—, —PR′—, —P(O)(OR′)—, —P(O)(OR′)O—, —P(O)(NR′R′)—, —P(O)(NR′R′)O—, P(O)(NR′R′)NR′—, —S(O)NR′—, and —S(O)₂NR′, with R′ being H, a C1-C6 alkyl, optionally partially halogenated.

According to a preferred embodiment, any A may optionally be substituted with one or several substituents independently selected from nitro, cyano, amino groups, and/or substituents selected from alkyl, alkenyl, alkynyl, haloalkyl, alkoxy, and alkoxyalkyl groups, including substituted substituents. Alkyl, alkenyl, alkynyl, haloalkyl, alkoxy and alkoxyalkyl are as defined below.

Preferably, further residues optionally present on A, such as R(w) in (tII), for example, are selected from C4-C30 alkenes comprising two or more conjugated double bonds.

Ra may be used as a residue capable of controlling the melting point of an organic, charge-transporting compound. The reference with respect to the ability to control the melting point is the same charge transporting material devoid of the at least one residue Ra. In particular, the function of Ra is to provide a charge transporting material that adopts the desired phase at the temperatures indicated herein. The adjustment of the melting point to obtain the desired characteristics in the temperature ranges indicated above may be brought about by a single residue Ra or a combination of identical or different residues Ra, present in any of the structures (tI)-(tV).

At least one linear, branched or cyclic residue containing one or several oxygen atoms may be used for lowering the melting point, and thus the absence of such residues or alternative residues may be used to correspondingly raise melting points, thus obtaining the desired characteristics. Other residues, include for example alkyls as defined below, may assist in the adjustment of the melting point and/or phase characteristics.

Ra may be halogenated and/or perhalogenated in that one, several or all H of the residue Ra may be replaced with halogens. Preferably, the halogen is fluorine.

If Ra is oxygen containing compound, it is preferably a linear, branched, or cyclic saturated C1-C30 hydrocarbon comprising 1-15 oxygen atoms, with the proviso that the number of oxygen atoms does preferably not exceed the number of carbons. Preferably, Ra comprises at least 1.1 to 2 as much carbon as oxygen atoms. Preferably, Ra is a C2-C20, saturated hydrocarbon comprising 2-10 oxygen atoms, more preferably a C3-C10 saturated hydrocarbon comprising 3-6 oxygen atoms.

Preferably, Ra is linear or branched. More preferably Ra is linear.

Preferably, Ra is selected from a C1-C30, preferably C2-C15 and most preferably a C3-C8 alkoxy, alkoxyalkyl, alkoxyalkoxy, alkylalkoxy group as defined below.

Examples of residues Ra may independently be selected from the following structures:

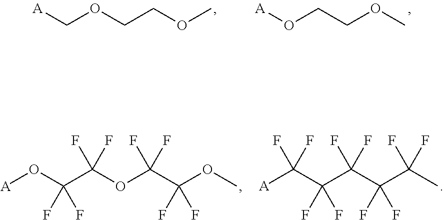

with A indicating any A in formula (tI-V) above.

Any Ra present may be linked to a carbon atom or a heteroatom optionally present in A. If Ra is linked to a heteroatom, it is preferably linked to a N-atom. Preferably, however, any Ra is linked to a carbon atom. Within the same structure (tI-tV), any Ra may be linked to a C or a heteroatom independently of another Ra present on the same A or in the same structure.

Preferably, every structure A, such as A, A₁, A₂, A₃ and A₄, if present in formulae (tI-tV) above comprises at least one residue Ra. For example, in the compound according to structure (tI-tV), at least one structure A comprises an oxygen containing residues Ra as defined above, whereas one or more other and/or the same A of the same compound comprise an aliphatic residue Ra, for example an alkyl group as defined below, preferably a C2-C20, more preferably C3-C15 alkyl, preferably linear.

The following definitions of residues are given with respect to all reference, to the respective residue, in addition to preferred definitions optionally given elsewhere. These apply specifically to the formulae relating to hole transporters (tN formulae) but may optionally also be applied to all other formulae herein where this does not conflict with other definitions provided.

An alkoxyalkoxy group above is an alkoxy group as defined below, which is substituted with one or several alkoxy groups as defined below, whereby any substituting alkoxy groups may be substituted with one or more alkoxy groups, provided that the total number of 30 carbons is not exceeded.

An alkoxy group is a linear, branched or cyclic alkoxy group having from 1 to 30, preferably 2 to 20, more preferably 3-10 carbon atoms.

An alkoxyalkyl group is an alkyl group as defined below substituted with an alkoxy group as defined above.

An alkyl group is a linear, branched and/or cyclic having from 1-30, preferably 2-20, more preferably 3-10, most preferably 4-8 carbon atoms. An alkenyl groups is linear or branched C2-C30, preferably C2-C20, more preferably C3-C10 alkenyl group. An alkynyl group is a linear or branched C2-C30, preferably C2-C20, more preferably C3-C10 linear or branched alkynyl group. In the case that the unsaturated residue, alkenyl or alkynyl has only 2 carbons, it is not branched.

A haloalkyl groups above is an alkyl groups as defined above which is substituted with at least one halogen atom.

An alkylalkoxy group is an alkoxy group as defined above substituted with at least one alkyl group as defined above, provided that the total number of 30 carbons is not exceeded.

The aryl group above and the aryl moiety of the aralkyl groups (which have from 1 to 20 carbon atoms in the alkyl moiety) and the aryloxy groups above is an aromatic hydrocarbon group having from 6 to 14 carbon atoms in one or more rings which may optionally be substituted with at least one substituent selected from the group consisting of nitro groups, cyano groups, amino groups, alkyl groups as defined above, haloalkyl groups as defined above, alkoxyalkyl groups as defined above and alkoxy groups as defined above.

The organic charge transporting material may comprise a residue Rp linked to an A. According to a preferred embodiment, Rp is selected from vinyl, allyl, ethinyl, independently from any other Rp optionally present on the A to which it is linked or optionally present on a different A within the structures (tI) and/or (tII).

The charge transporting material comprised in the device of the invention may be selected from compounds corresponding to the structures of formulae (tI-tV) as such. In this case, n, if applicable, is 1 and the charge transporting material comprises individual compounds of formulae (tI-tV), or mixtures comprising two or more different compounds according formulae (tI-tV).

The compounds of structures (tI-tV) may also be coupled (e.g. dimerised), olilgomerised, polymerized and/or cross-linked. This may, for example, be mediated by the residue Rp optionally present on any of the structures (tI-tV). As a result, oligomers and/or polymers of a given compound selected from (tI-tV) or mixtures of different compounds selected from structures (tI-tV) may be obtained to form a charge transporting material. Small n is preferably in the range of 2-10.

A particularly preferred organic molecular hole transporter contains a spiro group to retard crystallisation. A most preferred organic hole transporter is a compound of formula tXVII below, and is described in detail in Snaith et al. Applied Physics Letters 89 262114 (2006), which is herein incorporated by reference.

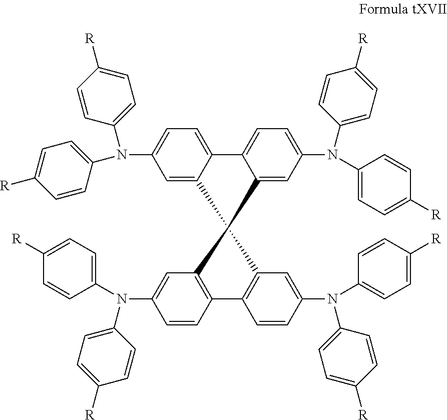

wherein R is alkyl or O-alkyl, where the alkyl group is preferably methyl, ethyl, n-propyl, iso-propyl, n-butyl, sec-butyl or tert-butyl, preferably methyl.

In all aspects, the n-type semiconductor material for use in the solid state heterojunctions (e.g. DSCs) relating to the present invention may be any of those which are well known in the art. Oxides of Ti, Al, Sn, Mg and mixtures thereof are among those suitable. TiO₂ and Al₂O₃ are common examples, as are MgO and SnO₂. The n-type material is used in the form of a layer and will typically be mesoporous providing a relatively thick layer of around 0.05-100 μm over which the second sensitizing agent may be absorbed at the surface.

In one optional but preferred embodiment, a thin surface coating of a high band-gap/high band gap edge (insulating) material, may be deposited on the surface of a lower band gap n-type semiconductor such as SnO₂. This can greatly reduce the fast recombination from the n-type electrode, which is a much more severe issue in solid state DSCs than in the more widely investigated electrolyte utilising cells. Such a surface coating may be applied before the oxide particles (e.g. SnO₂) are sintered into a film or after sintering.

The n-type material of the solid state heterojunctions relating to all aspects of the present invention is generally a metal compound such as a metal oxide, compound metal oxide, doped metal oxide, selenide, teluride, and/or multicompound semiconductor, any of which may be coated as described above. Suitable materials include single metal oxides such as Al₂O₃, ZrO, ZnO, TiO₂, SnO₂, Ta₂O₅, Nb₂O₅, WO₃, W₂O₅, In₂O₃, Ga₂O₃, Nd₂O₃, Sm₂O₃, La₂O₃, Sc₂O₃, Y₂O₃, NiO, MoO₃, PbO, CdO and/or MnO; compound metal oxides such as ZnₓTi_{y}O_{z}, ZrTiO₄, ZrW₂O₈, SiAlO_{3,5}, Si₂AlO_{5,5}, SiTiO₄ and/or AlTiO_{5;} doped metal oxides such as any of the single or compound metal oxides indicated above doped with at least one of Al, F, Ge, S, N, In, Mg, Si, C, Pb and/or Sb; carbides such as Cs₂C₅; sulphides such as PbS, CdS, CuS; selenides such as PbSe, CdSe; telurides such as CdTe; nitrides such as TiN; and/or multicompound semiconductors such as ClGaS₂.

It is common practice in the art to generate p-n heterojunctions, especially for optical applications, from a mesoporous layer of the n-type material so that light can interact with the junction at a greater surface than could be provided by a flat junction. In the present case, this mesoporous layer may be conveniently generated by sintering of appropriate semiconductor particles using methods well known in the art and described, for example in Green et al. (J. Phys. Chem. B 109 12525-12533 (2005)) and Kay et al. (Chem. Mater. 17 2930-2835 (2002)), which are both hereby incorporated by reference. With respect to the surface coatings, where present, these may be applied before the particles are sintered into a film, after sintering, or two or more layers may be applied at different stages.

Typical particle diameters for the semiconductors will be dependent upon the application of the device, but might typically be in the range of 5 to 1000 nm, preferably 10 to 100 nm, more preferably still 10 to 30 nm, such as around 20 nm. Surface areas of 1-1000 M² g⁻¹ are preferable in the finished film, more preferably 30-200 m² g⁻, such as 40-100 m² g⁻¹. The film will preferably be electrically continuous (or at least substantially so) in order to allow the injected charge to be conducted out of the device. The thickness of the film will be dependent upon factors such as the photon-capture efficiency of the photo-sensitizer, but may be in the range 0.05-100

μm, preferably 0.5 to 20 μm, more preferably 0.5-10 μm, e.g. 1 to 5 μm. In one alternative embodiment, the film is planar or substantially planar rather than highly porous, and for example has a surface area of 1 to 20 m² g⁻¹ preferably 1 to 10 m² g⁻¹. Such a substantially planar film may also or alternatively have a thickness of 0.005 to 5 μm, preferably 0.025 to 0.2 μm, and more preferably 0.05 to 0.1 μm.

Where the n-type material is surface coated, materials which are suitable as the coating material (the “surface coating material”) may have a conduction band edge closer to or further from the vacuum level (vacuum energy) than that of the principal n-type semiconductor material, depending upon how the property of the material is to be tuned. They may have a conduction band edge relative to vacuum level of at around −4.8 eV, or higher (less negative) for example −4.8 or −4.7 to −1 eV, such as −4.7 to −2.5 eV, or −4.5 to −3 eV

Suitable coating materials, where present, include single metal oxides such as MgO, Al₂O₃, ZrO, ZnO, HfO₂, TiO₂, Ta₂O₅, Nb₂O₅, WO₃, W₂O₅, In₂O₃, Ga₂O₃, Nd₂O₃, Sm₂O₃, La₂O₃, Sc₂O₃, Y₂O₃, NiO, MoO₃, PbO, CdO and/or MnO; compound metal oxides such as ZnₓTi_{y}O_{z}, ZrTiO₄, ZrW₂O₈, SiAlO_{3,5}, Si₂AlO_{5,5}, SiTiO₄ and/or AlTiO₅; doped metal oxides such as any of the single or compound metal oxides indicated above doped with at least one of Al, F, Ge, S, N, In, Mg, Si, C, Pb and/or Sb; carbonates such as Cs₂C₅; sulphides such as PbS, CdS, CuS; selenides such as PbSe, CdSe; telurides such as CdTe; nitrides such as TiN; and/or multicompound semiconductors such as ClGaS₂. Some suitable materials are discussed in Gratzel (Nature 414 338-344 (2001)). The most preferred surface coating material is MgO.

Where present, the coating on the n-type material will typically be formed by the deposition of a thin coating of material on the surface of the n-type semiconductor film or the particles which are to generate such a film. In most cases, however, the material will be fired or sintered prior to use, and this may result in the complete or partial integration of the surface coating material into the bulk semiconductor. Thus although the surface coating may be a fully discrete layer at the surface of the semiconductor film, the coating may equally be a surface region in which the semiconductor is merged, integrated, or co-dispersed with the coating material.

Since any coating on the n-type material may not be a fully discrete layer of material, it is difficult to indicate the exact thickness of an appropriate layer. The appropriate thickness will in any case be evident to the skilled worker from routine testing, since a sufficiently thick layer will retard electron-hole recombination without undue loss of charge injection into the n-type material. Coatings from a monolayer to a few nm in thickness are appropriate in most cases (e.g. 0.1 to 100 nm, preferably 1 to 5 nm).

The bulk or “core” of the n-type material in all embodiments of the present invention may be essentially pure semiconductor material, e.g. having only unavoidable impurities, or may alternatively be doped in order to optimise the function of the p-n-heterojunction device, for example by increasing or reducing the conductivity of the n-type semiconductor material or by matching the conduction band in the n-type semiconductor material to the excited state of the chosen sensitizer.

Thus the n-type semiconductor and oxides such as TiO₂, ZnO, SnO₂ and WO₃ referred to herein (where context allows) may be essentially pure semiconductor (e.g. having only unavoidable impurities). Alternatively they may be doped throughout with at least one dopant material of greater valency than the bulk (to provide n-type doping) and/or may be doped with at least one dopant material of lower valency than the bulk (to give p-type doping). n-type doping will tend to increase the n-type character of the semiconductor material while p-type doping will tend to reduce the degree of the natural n-type state (e.g. due to defects).

Such doping may be made with any suitable element including F, Sb, N, Ge, Si, C, In, InO and/or Al. Suitable dopants and doping levels will be evident to those of skill in the art. Doping levels may range from 0.01 to 49% such as 0.5 to 20%, preferably in the range of 5 to 15%. All percentages indicated herein are by weight where context allows, unless indicated otherwise.

The various aspects of the present invention include the use of an insulating barrier layer to inhibit the light induced drop in shunt resistance (and thus drop in efficiency) in a heterojunction such as a SDSC. Such a use will typically be in the absence of oxygen, since this is where the photo-induced drop in efficiency is most significant. This use thus applies particularly to any of the devices of the present invention, including those which are encapsulated, such as in the absence or substantial absence of oxygen.

The use of the present invention will preferably be to maintain the efficiency of a heterojunction at no less than 75%, preferably no less than 85% and more preferably no less than 95% of its initial efficiency for a period of no less than 20 minutes, preferably no less than 1 hour and more preferably no less than 12 hours under full sun illumination in the substantial absence of oxygen. As used herein, “substantial absence of oxygen” may be taken to indicate a level of oxygen of less than 10 ppm, preferably less than 1ppm in the surrounding atmosphere.

The method of the present invention relates to a method for the manufacture of a solid-state p-n heterojunction comprising a cathode separated from said n-type material by a porous barrier layer of at least one insulating material.

Preferred steps in the method of the invention comprise:
a) coating a cathode, preferably a transparent cathode (e.g. a Fluorinated Tin Oxide—FTO cathode) with a compact layer of an n-type semiconductor material (such as any of those described herein);
b) forming a porous (preferably mesoporous) layer of an n-type semiconductor material (such as any of those described herein) on said compact layer;
c) surface sensitizing said compact layer and/or said porous layer of n-type material with at least one sensitizing agent (as described herein);
d) forming a porous barrier layer of an insulating material on or over said porous layer of n-type material;
e) forming a layer of a solid state p-type semiconductor material (preferably an organic hole transporting material such as any of those described herein) in contact with said porous layer of an n-type semiconductor material and penetrating said porous barrier layer; and
f) forming an anode, preferably a metal anode (e.g. a silver or gold anode) on or over said porous barrier layer, in contact with said p-type semiconductor material.

The surface sensitizing of the layer (e.g. porous layer) of n-type semiconductor material is preferably by surface absorption of the sensitizing agent. This sensitizing agent may be absorbed by contact of the surface with a solution of the desired sensitizing agent. This step (step c) may be carried out before or after step d) (forming the barrier layer) but will preferably occur after forming the porous n-type material and before forming the layer of p-type material.

The step of forming an insulating barrier layer may be performed by any method suitable for generating a porous insulating layer from the material to be employed. Such methods include formation of a polymeric porous sheet and placing that between the n-type material and the cathode, depositing the material by evaporation, spraying (e.g. spray pyrolysis) or sputter deposition, or by forming a paste of insulating particles, followed by heating/sintering. Suitable methods are described in the Examples below.

The invention is illustrated further in the following non-limiting examples and in the attached Figures, in which:

FIG. 1—represents an organic solid state dye sensitised solar cell foamed with a mesoporous TiO₂ or mesoporous SnO₂ n-type semiconductor material;

FIG. 2—shows a schematic representation of charge transfers taking place in DSC operation by indicates light absorption, e⁻inj=electron injection, rec=recombination between electrons in the n-type and holes in the p-type material, h⁺inj=hole-transfer (dye regeneration), CB=conduction band;

FIG. 3—represents a graph of the observed current/voltage characteristics for a SnO₂ based dye-sensitized solar cell measured under AM1.5 simulated sun light of 100 mWcm⁻², in air (solid-squares) and when encapsulated in an air free environment (1 ppm oxygen) (open-symbols). The 1st, 2nd 3rd and 4th scan of the encapsulated cell were taken at 1 minute intervals;

FIG. 4—represents “Schottky diodes” composed of consecutive layers of a) FTO, MgO coated SnO₂ and Ag; and b) FTO, MgO coated SnO₂, Al₂O₃, and Ag;

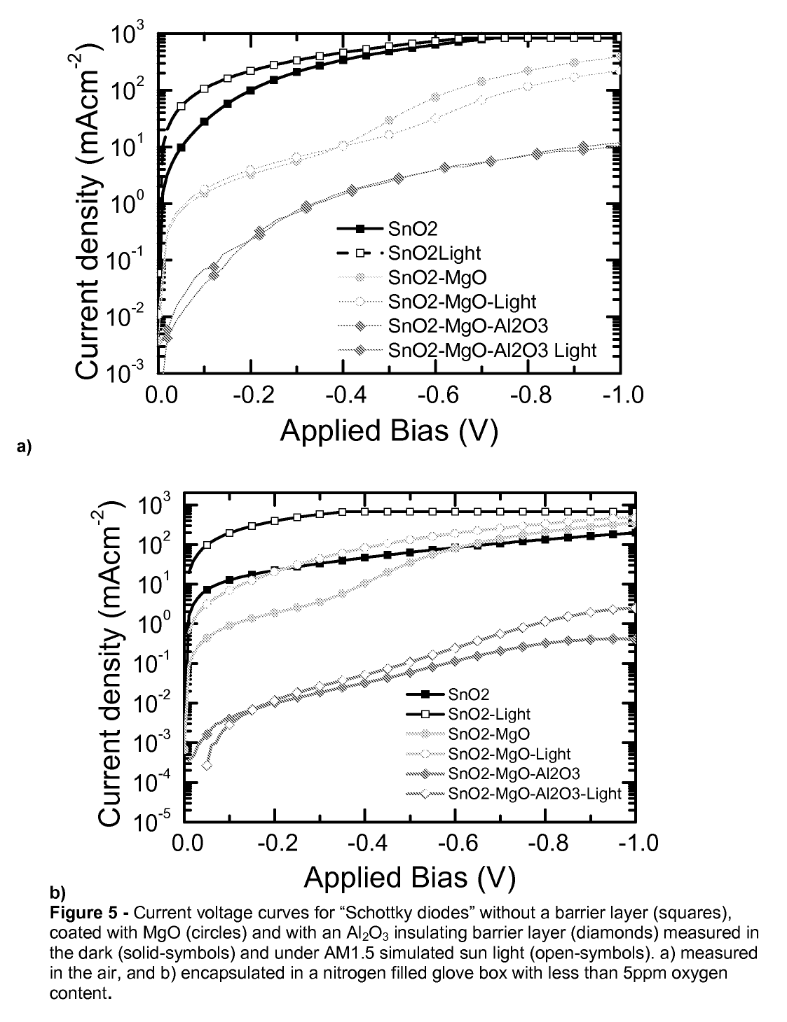

FIG. 5—shows current voltage curves for “Schottky diodes” composed of FTO—SnO₂—Ag (squares), FTO—MgO coated SnO₂—Ag (circles) and FTO—MgO coated SnO₂—Al₂O₃—Ag (diamonds) measured in the dark (solid-symbols) and under AM1.5 simulated sun light (open-symbols). a) measured in the air, and b) encapsulated in a nitrogen filled glove box with ˜1ppm oxygen;

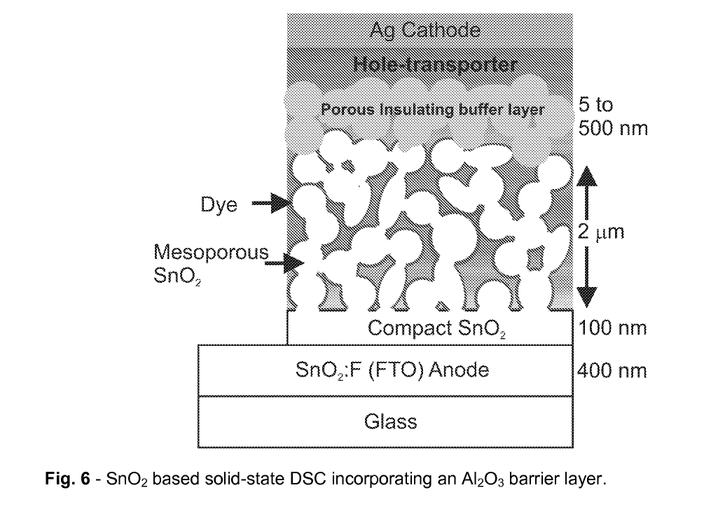

FIG. 6—shows a schematic representation of a SnO₂ based solid-state DSC incorporating an Al₂O₃ barrier (buffer) layer; and

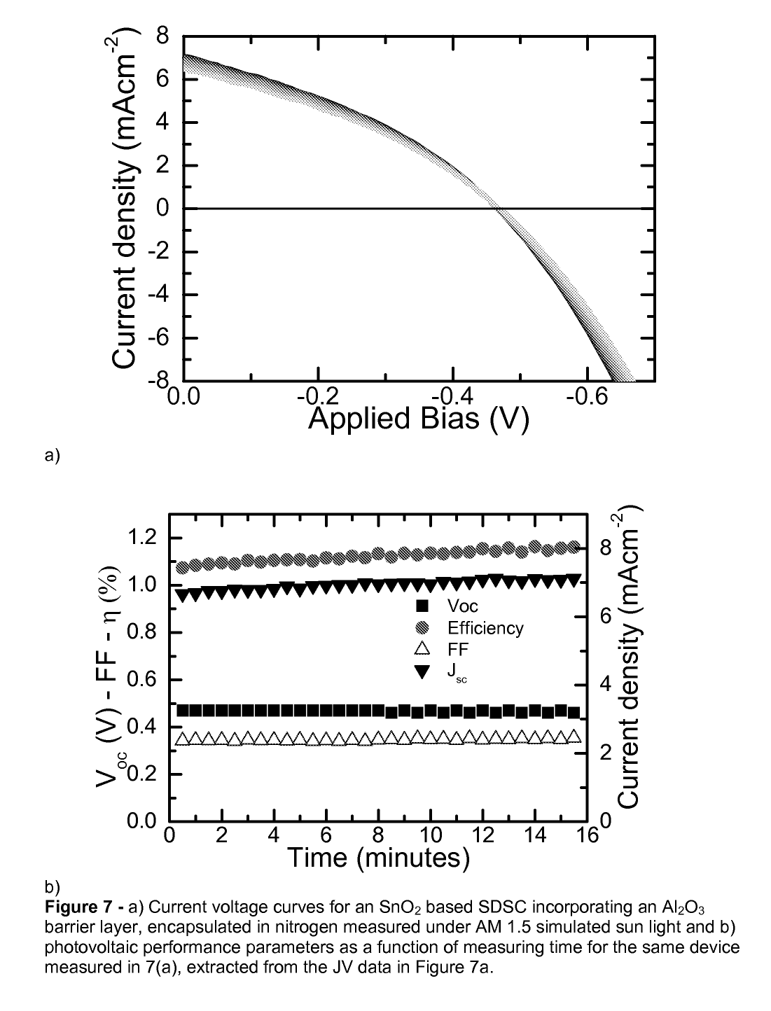

FIG. 7a) shows current voltage curves for an SnO₂ based solid-state DSC incorporating an Al₂O₃ buffer layer, encapsulated in a nitrogen filled glove box with ˜1 ppm oxygen, measured under AM 1.5 simulated sun light. In 7(a) 20 scans are plotted with the first scan in light grey and the last scan in black, the time between each scan was ˜40 seconds;

b) shows photovoltaic performance parameters as a function of measuring time for the same device measured in 7(a), extracted from the JV data in FIG. 7a.

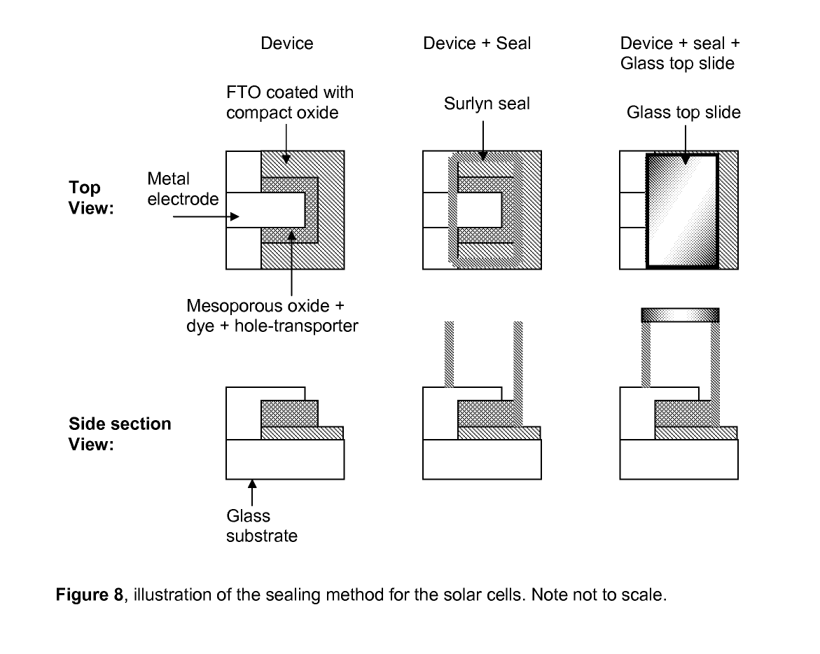

FIG. 8 shows an illustration of the sealing method for the solar cells (not to scale). The sealant thickness was ˜50 μm, the thickness of the mesoporous oxide was ˜2 μm. The total substrate size was 1.4 cm×1.4 cm. The active area, defined by the overlap of the top metallic electrode and the underlying FTO was ˜0.12 cm⁻². The FTO layer was ˜350 nm thick, the compact oxide layer was ˜100 nm thick, the Glass substrates were 3.2 mm thick, and the top glass slides were ˜1 mm thick. The glass top slide was ˜1.3 cm×0.8 cm in size, the Surlyn was of the same outer dimensions with a ˜1 mm wide frame.

### EXAMPLE 1

### Formation of Solid-Phase Dye Sensitised Solar Cells—TiO₂ based DSCs

Dye-sensitized solar cells of the present invention may be fabricated using known methods, including techniques such as described in Kavan, L. and Gratzel, M. Electrochim. Acta 40, 643 (1995) and Snaith, H. J. and Gratzel, M., Adv. Mater. 18, 1910 (2006).

### 1.1—Cleaning and Etching of the Electrodes

The dye-sensitized solar cells used and presented in these examples were fabricated as follows: Fluorine doped tin oxide (FTO) coated glass sheets (15 Ω/square, Pilkington USA) were etched with zinc powder and HCl (4N) to give the required electrode pattern. The sheets were subsequently cleaned with soap (2% helmanex in water), distilled water, acetone, ethanol and finally treated under oxygen plasma for 10 minutes to remove any organic residues.

### 1.2—Deposition of the Compact TiO₂ Layer

The FTO sheets were then coated with a compact layer of TiO₂ (100 nm) by aerosol spray pyrolysis deposition of a Ti-ACAC ethanol solution (1:10 Ti-ACAC to ethanol volume ratio) at 450° C. using air as the carrier gas (see Kavan, L. and Gratzel, M., Highly efficient semiconducting TiO₂ photoelectrodes prepared by aerosol pyrolysis, Electrochim. Acta 40, 643 (1995); Snaith, H. J. and Gratzel, M., The Role of a “Schottky Barrier” at an Electron-Collection Electrode in Solid-State Dye-Sensitized Solar Cells. Adv. Mater. 18, 1910 (2006).

### 1.3—Preparing the Mesoporous TiO₂ Electrodes

A standard TiO₂ nanoparticle paste was doctor-bladed onto the compact TiO₂ to give a dry film thickness between 1 and 3 μm, governed by the height of the doctor blade. These sheets were then slowly heated to 500° C. (ramped over 30 minutes) and baked at this temperature for 30 minutes under an oxygen flow. After cooling, the sheets were cut into slides of the required size and stored in the dark until further use.

Prior to fabrication of each set of devices, the nanoporous films were soaked in a 0.02 M aqueous solution of TiCl₄ for 1 hours at 70° C. This procedure was applied to grow a thin shell of TiO₂ upon both the TiO₂. Following the TiCl₄ treatment the films were rinsed with deionised water, dried in air, and baked once more at 500° C. for 45 minutes under oxygen flow. Once cooled to 70° C. they were placed in a dye solution overnight.

The ruthenium-based dye used for sensitization was “Z907”, an NCS bipyridyl complex (see Schmidt-Mende, L., Zakeeruddin, S. M., and Gratzel, M., Efficiency improvement in solid-state dye-sensitized photovoltaics with an amphiphilic ruthenium-dye, Applied Physics Letters 86 (1), 013504 (2005)). The dye solution comprised 0.5 mM of Z907 in acetonitrile and tert-butyl alcohol (volume ratio: 1:1).

### 1.4—Hole-Transporter Deposition and Device Assembly

The hole transporting material used was spiro-OMeTAD, which was dissolved in chlorobenzene at a typical concentration of 180 mg/ml. After fully dissolving the spiro-OMeTAD at 100° C. for 30 minutes the solution was cooled and tertbutyl pyridine (tBP) was added directly to the solution with a volume to mass ratio of 1:26 μl/mg tBP:spiro-MeOTAD. Lithium bis(trifluoromethylsulfonyl)amine salt (Li-TFSI) ionic dopant was pre-dissolved in acetonitrile at 170 mg/ml, then added to the hole-transporter solution at 1:12 μl/mg of Li-TFSI solution:spiro-MeOTAD. The dye coated mesoporous films (with and without Au@Si nanoparticles) were briefly rinsed in acetonitrile and dried in air for one minute. A small quantity (20 to 70 μl) of the spiro-OMeTAD solution was dispensed onto each dye coated substrate and left for 20 s before spin-coating at 2000 rpm for 25 s in air. The films were then placed in a thermal evaporator where 150 nm thick silver electrodes were deposited through a shadow mask under high vacuum (10⁻⁶ mBar).

An insulating barrier layer was then incorporated according to one of the methods indicated below in examples 2-2.1 to 2.5. The device was then placed in the thermal evaporator and silver electrodes were deposited through a shadow mask as standard.

### EXAMPLE 2

### Experimental Procedures for Insulating Barrier Layer Inclusion

The devices are fabricated as previously described up to the deposition of the mesoporous n-type material.

After n-type material deposition the substrates can be optionally heat treated to sinter the mesoporous electrode.

Following this optional sintering, or directly after n-type mesoporous film deposition the insulating interlayer can be deposited by any of but not limited to the following techniques:

### 2.1. Spray Pyrolysis of Insulating Oxide, For Example Al₂O₃

Aluminum-Ac Ac 99% is dissolved in N,N-Dimethylformamide 99.8% purchased from Sigma Aldrich, 100 mMolar, and stirred at room temperature for 2 hours. The solution is then deposited on top of the mesoporous n-type electrodes via spray pyrolysis deposition (SPD) sprayed at 500 C, to give a layer thickness of between 1 and 100 nm, preferably between 2 and 10 nm.

After deposition of the insulating Al₂O₃ interlayer via spray pyrolysis deposition, the substrates were cooled, and immersed in dye, with the subsequent device fabrication as described for a standard device.

### 2.2. Evaporative Deposition of Insulating Oxide

After mesoporous film deposition and sintering, the substrates were loaded into a thermal evaporator whereupon a thin layer of aluminium was evaporated directly upon the exposed surface of the mesoporous n-type electrodes at low pressure (10⁻⁶ mbar), with an aluminium metal layer thickness ranging from 0.5 to 50 nm, preferably 2 to 10 nm, most preferably 5 nm. The substrates were subsequently resintered to 500 degrees in air, which converted the aluminium metal into aluminium oxide, resulting in the creation of the thin insulating interlayer. Upon cooling the devices were placed in dye solution, and subsequent device fabrication proceeded following standard protocol.

### 2.3. Sputter Deposition of Insulating Oxide

After mesoporous film deposition and sintering, the substrates were loaded into a sputter coater whereupon a thin layer of aluminium oxide was sputtered directly upon the exposed surface of the mesoporous n-type electrodes at low pressure in a mixed atmosphere of oxygen and argon. The resulting aluminium oxide layer thickness ranged from 0.5 to 50 nm, preferably 2 to 10 nm, most preferably 5 nm. The substrates were optionally resintered, and subsequently placed in dye solution, with the remainder of the device fabrication procedure following standard protocol.

### 2.4. Insulating Mesoporous Paste

### 2.4a: Al₂O₃ Paste

Aluminum oxide dispersion was purchased from Sigma-Aldrich (10% wt in water) and was washed in the following manner: it was centrifuged at 7500 rpm for 6 h, and redispersed in Absolute Ethanol (Fisher Chemicals) with an ultrasonic probe; which was operated for a total sonication time of 5 minutes, cycling 2 seconds on, 2 seconds off. This process was repeated 3 times.

For every 10 g of the original dispersion (1 g total Al₂O₃) the following was added: 3.33 g of α-terpineol and 5 g of a 50:50 mix of ethyl-cellulose 10 cP and 46 cP purchased from Sigma Aldrich in ethanol, 10% by weight. After the addition of each component, the mix was stirred for 2 minutes and sonicated with the ultrasonic probe for 1 minute of sonication, using a 2 seconds on 2 seconds off cycle.

Finally, the resulting mixture was introduced in a Rotavapor to remove excess ethanol and achieve the required thickness when doctor blading, spin-coating or screen printing.

The paste was applied on top of the mesoporous n-type electrodes, via screen printing, doctor blade coating or spin-coating, through a suitable mesh, doctor blade height or spin-speed to create a film with an average thickness of between 10 to 1000 nm, preferably 20 to 100 nm, and most preferably 30 to 70 nm.

The films were subsequently resintered to 450 degrees Celsius, cooled and submersed in dye, following the standard device fabrication protocol.

### 2.4b SiO₂ Paste

SiO₂ particles were synthesized utilizing the following procedure (see G. H. Bogush, M. A. Tracy, C. F. Zukoski, Journal of Non-Crystalline Solids 1988, 104, 95.):

2.52 ml of deionized water were added into 59.2 ml of absolute ethanol (Fisher Chemicals). This mixture was then stirred violently for the sequential addition of the following reactives: 0.47 ml of Ammonium Hydroxide 28% in water (Sigma Aldrich) and 7.81 ml of Tetraethyl Orthosilicate (TEOS) 98% (Sigma Aldrich). The mixture was then stirred for 18 hours to allow the reaction to complete.

The silica dispersion was then washed following the same washing procedure as outlined previously for the Al₂O₃ paste (Example 2.4a).

The amount of silica was then calculated assuming that all the TEOS reacts. In our case, 2.1 g of SiO₂ was the result of the calculation.

For every 1 g of calculated SiO₂ the following were added: 5.38 g of anhydrous terpineol (Sigma Aldrich) and 8 g of a 50:50 mix of ethyl-cellulose 5-15 mPa·s and 30-70 mPa·s purchased from Sigma Aldrich in ethanol, 10% by weight. After the addition of each component, the mix was stirred for 2 minutes and sonicated with the ultrasonic probe for 1 minute of sonication, using a 2 seconds on 2 seconds off cycle.

The remainder of the insulating interlayer inclusion and device fabrication was carried out as described for the Al₂O₃ mesoporous interlayer.

### 2.5. Self-Assembled Blocking Layer

Block copolymers were used to self-assemble mesoporous insulating buffer layers. Here we describe the use of an aluminosilicate blocking layer. A prehydrolyzed sol was prepared by mixing 5.3 g of (3-glycidyloxypropyl)trimethoxysilane (GLYMO) and 1.4 g of aluminum(III) sec-butoxide (Al(OsBu)₃) (mole ratio of 8:2) and 38 mg of KCl (7.5 wt % with respect to the mass of polymer) in a 100 mL beaker. This mixture was stirred vigorously for 1-2 min at room temperature before 0.27 g of 0.01M HCl (15% of the stoichiometric amount required for the complete hydrolysis of the metal alkoxide groups) was added. After 30 min of stirring the sol at room temperature, 1.7 g of 0.01 M HCl (the residual amount for complete hydrolysis with a 25% molar excess) was added, and the mixture was stirred for another 20 min. Thereafter the required amount of this mixture was filtered through a 0.2 μmPTFE filter and added to the block copolymer solution. This block copolymer solution consisted of 0.5 g of PI-b-PEO dissolved in a 1:1 mixture of chloroform and THF by weight (5 wt % polymer solution). The resulting mixture was stirred for another hour before being doctor bladed on top of the mesoporous n-type metal oxide substrate and aged at 50 C for 4 hours prior to the final calcination step. Prior to doctor blade coating of the aluminosilicate sol, the mesoporous metal oxide films were freshly screen printed, and heated to 150 degrees to evaporate all the solvent from within. After the doctor blade coating of the aluminosilicate sol, the films were slowly ramped to 500 degrees for 30 minutes, and complete device fabrication was conducted as described from step 1.3 above.

Optionally, prior to doctor blade coating of the aluminosilicate sol, the mesoporous n-type films had been sintered once to 500 degrees, and had a chemical bath surface treatment of TiCl₄ as described in 1.3 above. Prior to resintering however, the aluminosilicate sol was doctor blade coated upon the mesoporous n-type films, and subsequently heated to 500 degrees for 45 minutes, cooled and immersed in dye, with the subsequent device fabrication as described in 1.3 and 1.4 above.

### EXAMPLE 3

### Testing in the Absence of Oxygen

SDSCs tested initially were formed by the method of Example 1 (without the barrier layer of Example 2) and encapsulated in a glove-box under a positive pressure of nitrogen. The encapsulation was performed by sealing the device to a glass slide with a Surlyn (Dupont) hot melt seal. The Surlyn was cut into a rectangle with the centre removed and placed on top of the solar cell, as to completely cover the active area of the devices. A microscope slide was also cut to the same dimensions as the Surlyn seal and placed on top of the seal. The “sandwiched” structure was then placed on top of a hotplate set at 150 degrees centigrade in the nitrogen filled glove box for 20 seconds, with applied pressure. This resulted in the seal softening, and creating an air tight seal between the solar cell and the top glass slide. This is illustrated in FIG. 8. Optionally, epoxy resin was coated around the outside of the seal on the sealed devices in the nitrogen filled glove box and allowed to set overnight in the nitrogen filled glove box to add another layer of sealant.

In the example shown in FIG. 8, the sealant thickness was ˜50 μm, the thickness of the mesoporous oxide was ˜2 μm. The total substrate size was 1.4 cm×1.4 cm. The active area, defined by the overlap of the top metallic electrode and the underlying FTO was ˜0.12 cm⁻². The FTO layer was ˜350 nm thick, the compact oxide layer was ˜100 nm thick, the Glass substrates were 3.2 mm thick, and the top glass slides were ˜1 mm thick. The glass top slide was ˜1.3 cm×0.8 cm in size, the Surlyn was of the same outer dimensions with a ˜1 mm wide frame.

Once sealed (or optionally unsealed) the devices were removed from the glove box and tested in air by measuring current voltage characteristics using a PC coupled Keithley 2400 sourcemeter, in the dark and under simulated AM1.5 sun light. The sun light was generated from a Class AAB Abet technologies Sun 2000 solar simulator, which incorporated an AM1.5 filter.

The results for encapsulated SnO₂ based devices are shown in FIG. 3 and clearly demonstrate a dramatic decrease in cell voltage and fill-factor between each scan (approximately 1 minute intervals). This clearly demonstrates that SDSCs which have been found reasonably stable for hours or days in air lose their conversion efficiency within minutes of full-sun illumination in the absence of oxygen.

### EXAMPLE 4

### Diode Testing

In order to test the effect of a possible barrier layer, simplified diodes were constructed by the methods described in examples 1 and 2, except that no dye sensitizer nor hole-transporter were applied. The simple diodes were optionally encapsulated by the same method as used for the solar cells and the current voltage characteristics of the simplified diodes were tested in the same manner as for the solar cells,

The results shown in FIG. 4 demonstrate that both under light and dark conditions, the addition of a barrier layer reduces the current density in the diodes by 2 to 3 orders of magnitude in comparison with devices having no barrier layer. The use of a thin MgO coating on the SnO₂ particles provides some improvement but when encapsulated this is only marginal in comparison to the influence of the insulating barrier layer.

### EXAMPLE 5

### Testing SDSCs with a Barrier Layer

SDSCs utilising a SnO₂ mesoporous n-type material and an Al₂O₃ barrier layer were formed by the methods of Examples 1 and 2. These SDSCs were encapsulated in a nitrogen-filled glove box as with example 3, and illuminated under simulated full-sun conditions for several minutes.

The voltage, fill factor and overall efficiency of the devices after 16 minutes of illumination was found to be marginally superior to the performance when first exposed to light, indicating that the performance degradation previously observed under illumination in nitrogen was effectively eliminated by the addition of the barrier layer.

1. A solid-state p-n heterojunction comprising an organic p-type material in contact with an n-type material, and a cathode separated from said n-type material by a porous barrier layer of at least one insulating material.

2. A solid-state p-n heterojunction as claimed in claim 1, wherein said heterojunction is sensitized by at least one sensitizing agent.

3. A solid-state p-n heterojunction as claimed in claim 1 wherein said n-type material and said cathode are separated by a distance of no less than 1 nm at their closest point, by said porous barrier layer.

4. A solid-state p-n heterojunction as claimed in claim 1 wherein said n-type material and said cathode are separated by said porous barrier layer of at least one insulating material, over substantially all of the overlapping area between said n-type material and said cathode.

5. A solid-state p-n heterojunction as claimed in claim 1 comprising a solid p-type material as a hole transporter in the form of an organic semiconductor.

6. A solid-state p-n heterojunction as claimed in claim 1, wherein said insulating porous barrier layer comprises at least one insulating metal oxide.

7. A solid-state p-n heterojunction as claimed in claim 6 wherein said insulating metal oxide is selected from the group consisting of Al₂O₃, SiO₂, ZrO, MgO, HfO₂, Ta₂O₅, Nb₂O₅, Nd₂O₃, Sm₂O₃, La₂O₃, Sc₂O₃, Y₂O₃, NiO, MoO₃, MnO, SiAlO_{3,5}, Si₂AlO_{5,5}, SiTiO₄, AlTiO₅ and mixtures thereof.

8. A solid-state p-n heterojunction as claimed in claim 1, wherein said insulating porous barrier layer comprises at least one insulating polymer and/or block copolymer.

9. A solid-state p-n heterojunction as claimed in claim 8 wherein said insulating polymer is selected from the group consisting of poly-styrene, acrelate, methacrylate, methylmethacrylate, ethelene oxide, ethelene glycol, cellulose, imide polymers and mixtures thereof.

10. A solid-state p-n heterojunction as claimed in claim 8 wherein said insulating block copolymer is selected from the group consisting of polyisoprene-block-polystyrene, poly(ethylene glycol)-block-polypropylene glycol)-block-poly(ethylene glycol), polystyrene-block-polylactide, polystyrene-block-poly(ethylene oxide) and mixtures thereof.

11. A solid-state p-n heterojunction as claimed in claim 1, wherein said insulating porous barrier layer has a thickness of 1 to 1000 nm.

12. A solid-state p-n heterojunction as claimed in claim 1, wherein said insulating porous barrier layer has a porosity of 10 to 90%.

13. A solid-state p-n heterojunction as claimed in claim 1, wherein said insulating porous barrier layer is composed of material having a resistivity of greater than 10⁹ Ωcm.

14. A solid state p-n heterojunction as claimed in claim 2, wherein said sensitizing agent comprises at least one dye selected from the group consisting of a ruthenium complex dye, a metal-phalocianine complex dye, a metal-porphryin complex dye, a squarine dye, a thiophene based dye, a fluorine based dye, a polymer dye, and mixtures thereof.

15. A solid state p-n heterojunction as claimed in claim 1 wherein said p-type material is an organic hole-transporter.

16. A solid state p-n heterojunction as claimed in claim 15 wherein said organic hole-transporter comprises at least one optionally olilgomerized, polymerized and/or cross-linked compound of formula (tI), (tII), (tIII), (tIV) and/or (tV) below, 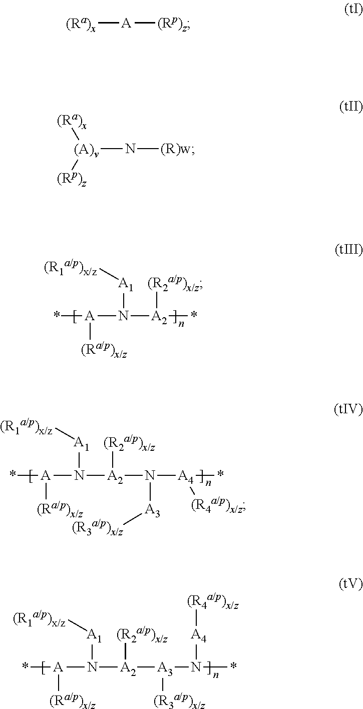
wherein
N, if present, is a nitrogen atom;
n, if applicable, is in the range of 1-20;
A is a mono-, or polycyclic system comprising at least one pair of a conjugated double bond (—C═C—C═C—), the cyclic system optionally comprising one or more heteroatoms, and optionally being substituted, whereby in a compound comprising more than one structures A, each A may be selected independently from another A present in the same structure (tI-tV);
each of A₁-A₄, if present, is an A independently selected from the A as defined above; v in (tII) recites the number of cyclic systems A linked by a single bond to the nitrogen atom and is 1, 2 or 3;
(R)w is an optional a hydrocarbon residue comprising from 1 to 30 carbon atoms, optionally substituted and optionally comprising 1 or more heteroatoms, with w being 0, 1 or 2 provided that v+w does not exceed 3, and, if w=2, the respective Rw₁ or Rw₂ being the same or different;
R^{a} represents a residue capable, optionally together with other R^{a} present on the same structure (tI-tV), of decreasing the melting point of an organic compound and is a linear, branched or cyclic alkyl or a residue comprising one or more oxygen atoms, wherein the alkyl and/or the oxygen comprising residue is optionally halogenated;
x is the number of independently selected residues R^{a} linked to an A and is selected from 0 to a maximum possible number of substituents of a respective A, independently from the number x of other residues R^{a} linked to another A optionally present;
with the proviso that per structure (tI-tV) there is at least one R^{a} being an oxygen containing residue as defined above; and, if more than one R^{a} are present on the same structure (tI-tV), they are the same or different; and wherein two or more R^{a} may form an oxygen-containing ring;
R^{p} represents an optional residue enabling a polymerization reaction with compounds comprising structure (tI-tV) used as monomers, and/or a cross-linking reaction between different compounds comprising structures (tI-tV);
z is the number of residues R^{p} linked to an A and is 0, 1, and/or 2, independently from the number z of other residues R^{p} linked to another A optionally present;
R^{p} may be linked to an N-atom, to an A and/or to a substituent R^{p} of other structures according (tI-tV), resulting in repeated, cross-linked and/or polymerized moieties of (tI-tV); and
(R^{a/p})_{x/z} and (R₁₋₄^{a/p})_{x/z}, if present, represent independently selected residues R^{a} and R^{p} as defined above.

17. A solid state p-n heterojunction as claimed in claim 15 wherein said organic hole-transporter is a compound of formula tXVII below: 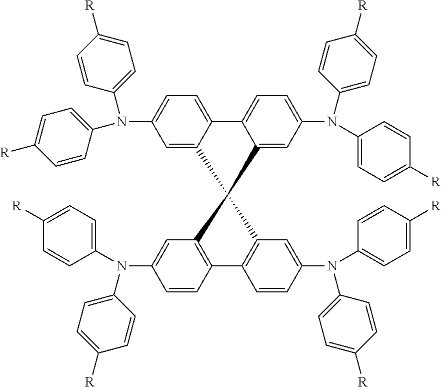
Formula tXVII
wherein R is C₁-C₆ alkyl or C₁-C₆ O-alkyl.

18. A solid state p-n heterojunction as claimed in claim 1, wherein said n-type material comprises at least one semiconductor material selected from the group consisting of single metal oxide, compound metal oxide, doped metal oxide, carbonate, sulphide, selenide, teluride, nitrides, multicompound semiconductor, and combinations thereof.

19. A solid state p-n heterojunction as claimed in claim 1, wherein said n-type material is porous.

20. A solid-state p-n heterojunction as claimed in claim 1, wherein said n-type material is selected from the group consisting of oxides of Ti, Zn, Sn, W and mixtures thereof, and wherein said n-type material is optionally surface coated.

21. A solid state p-n heterojunction as claimed in claim 1, wherein said n-type material is essentially pure material or is doped throughout with at least one dopant material of greater valency than the bulk material (n-type doping) and/or is doped with at least one dopant material of lower valency than the bulk (p-type doping), and wherein said n-type material is optionally surface coated.

22. An optoelectronic device comprising at least one solid state p-n heterojunction as claimed in claim 1.

23. An optoelectronic device as claimed in claim 22 wherein said device is a solar cell or photo-detector.

24. A device as claimed in claim 23 wherein said device is encapsulated so as to be substantially isolated from atmospheric oxygen.

25. A method of using a porous barrier layer in a solid-state p-n heterojunction, wherein said porous barrier layer reduces the light-induced drop in shunt resistance in a solid-state p-n heterojunction under anaerobic conditions.

26. The method as claimed in claim 25, wherein said porous barrier layer maintains the efficiency of said heterojunction at no less than 75% of its initial efficiency for a period of no less than 20 minutes under full sun illumination in the substantial absence of oxygen.

27. The method as claimed in claim 26 wherein said heterojunction is a solid state p-n heterojunction as claimed in claim 1.

28. The method as claimed in claim 25, wherein said solid-state p-n heterojunction is in a solar cell.

29. A method of preparing a solid-state p-n heterojunction comprising a cathode separated from said n-type material by a porous barrier layer of at least one insulating material, said method comprising:
a) coating an anode with a compact layer of an n-type semiconductor material;
b) forming a porous layer of an n-type semiconductor material on said compact layer,
c) surface sensitizing said compact layer and/or said porous layer of n-type semiconductor material with at least one sensitizing agent;
d) forming a porous barrier layer of an insulating material on said porous layer of n-type semiconductor material;
e) forming a layer of a solid state p-type semiconductor material in contact with said porous layer of n-type semiconductor material and penetrating said porous barrier layer; and
forming a cathode on said porous barrier layer, in contact with said p-type semiconductor material.

30. An optoelectronic device comprising at least one solid-state p-n heterojunction formed or formable by the method of claim 29.

31. The solid-state p-n heterojunction of claim 5, wherein the hole transporter is a molecular, oligomeric or polymeric hole transporter.

32. The solid state p-n heterojunction of claim 15, wherein said organic hole-transporter is a molecular organic hole transporter.

33. The solid state p-n heterojunction of claim 18, wherein said n-type material is TiO₂, SnO₂ or ZnO.

34. The solid state p-n heterojunction of claim 19, wherein said n-type material has a surface area of 1-1000 M² g⁻¹.

35. The solid state p-n heterojunction of claim 19, wherein said n-type material is in the form of an electrically continuous layer.

36. The solid state p-n heterojunction of claim 19, wherein said n-type material has a thickness of 0.1 to 20 μm.

37. The optoelectronic device of claim 23, wherein said solar cell is a solid state dye sensitized solar cell.

38. The method of claim 29, wherein said anode is a transparent anode.

39. The method of claim 29, wherein said anode is a fluorine-doped tin oxide cathode.

40. The method of claim 29, wherein said porous layer of n-type semiconductor material is mesoporous.

41. The method of claim 29, wherein said solid state p-type semiconductor material is an organic hole transporting material.

42. The method of claim 29, wherein said cathode is a metal cathode.

43. The method of claim 42, wherein said metal cathode is a silver or gold cathode.

44. The optoelectronic device of claim 30, wherein said optoelectronic device is a photovoltaic cell or light sensing device.
